(19) United States
(12) Patent Application Publication
(10) Pub. No.: US 2009/0199075 A1
(43) Pub. Date: Aug. 6, 2009

(54) Array form reed-solomon implementation as an instruction set extension

(76) Inventors: Victor Demjanenko, Pendleton, NY (US); Michael Terhaar, Amherst, NY (US)

Correspondence Address: Victor Demjanenko, Ph. D.;VOCAL Technologies, Ltd., 90A John Muir Drive, Buffalo, NY, 14228, US

(21) Appl. No.: 10/722,011

(22) Filed: Nov. 25, 2003

Related U.S. Application Data
(60) Provisional application No. 60/428,835, filed on Nov. 25, 2002.
(60) Provisional application No. 60/435,356, filed on Dec. 20, 2002.

(51) Int. Cl. H03M 13/07; G06F 11/10

(52) U.S. Cl. 714/784; 714/E11.033

(57) ABSTRACT

A parallelized or array method is developed for the generation of Reed Solomon parity bytes which utilizes multiple digital logic operations or computer instructions implemented using digital logic. At least one of the operations or instructions used performs the following combinations of steps: a) provide an operand representing N feedback terms where N is greater than one, b) computation of N by M Galios Field polynomial multiplications where M is greater than one, and c) computation of (N−1) by M Galios Field additions producing M result bytes. In this case the result bytes are used to modify the Reed Solomon parity bytes in either a separate operation or instruction or as part of the same operation.

A parallelized or array method is also developed for the generation of Reed Solomon syndrome bytes which utilizes multiple digital logic operations or computer instructions implemented using digital logic. At least one of the operations or instructions performs the following combinations of steps: a) provide an operand representing N data terms where N is one or greater, b) provide an operand representing M incoming Reed Solomon syndrome bytes where M is greater than one, c) computation of N by M Galios Field polynomial multiplications, d) computation of N by M Galios Field additions producing M modified Reed Solomon syndrome bytes.

The values of N and M may be selected to match the word width of the candidate MIPS microprocessor which is 32 bits or four bytes. When N and M are both have the value of four, sixteen Galios Field polynomial multiplications may be computed concurrently or sequentially in a pipeline. Each Galios Field polynomial multiplication utilizes a coefficient delivered from a memory device, which in a preferred embodiment, would be implemented either by a read only memory (ROM), random access memory (RAM) or a register file. The generation of Reed Solomon parity bytes requires several iterations each time using previous modified Reed Solomon parity bytes as incoming Reed Solomon parity bytes. Similarly, the generation of Reed Solomon syndrome bytes requires several iterations each time using previous modified Reed Solomon syndrome bytes as incoming Reed Solomon syndrome bytes.

### CONTINUATION DATA

This patent application claims the benefit under 35 U.S.C. Section 119(e) of U.S. Provisional Patent Application Ser. No. 60/428,835, filed on Nov. 25, 2003 and the Provisional Patent Application Ser. No. 60/435,356, filed on Dec. 20, 2002 both of which are incorporated herein by reference.

### COMPUTER PROGRAM LISTING APPENDIX

Incorporated by reference herein is a computer program listing appendix submitted on compact disk herewith and containing ASCII copies of the following files: ccsds_tab.c 2,626 byte created Nov. 18, 2002; compile_patent.h 5,398 byte created Nov. 20, 2002; decode_rs.c 7,078 byte created Nov. 25, 2002; decode_rs_opt_hw.c 27,624 byte created Dec. 20, 2002; decode_rs_opt_sw.c 12,543 byte created Dec. 20, 2002; decode_rs_patent.c 120,501 byte created Dec. 20, 2002; encode_rs.c 4,136 byte created Nov. 20, 2002; encode_rs_opt_hw.c 20,920 byte created Dec. 20, 2002: encode_rs_opt_sw.c 11,549 byte created Dec. 20, 2002; encode_rs_patent.c 115,417 byte created Dec. 20, 2002; fixed.h 973 byte created Jan. 1, 2002; fixed_opt.h 2,042 byte created Nov. 25, 2002; gf_mult.c 11,841 byte created Dec. 14, 2002; gf_mult.h 1,155 byte created Dec. 14, 2002; hw.c 3,166 byte created Nov. 25, 2002; main.c 3,730 byte created Nov. 21, 2002; main_opt.c 4,537 byte created Nov. 25, 2002; main_patent.c 4,606 byte created Dec. 10, 2002; result 1,583 byte created Dec. 20, 2002 and ti_rs_{—}62x.pdf 711,265 byte created Dec. 17, 2002

### FIELD OF THE INVENTION

The present invention relates to the implementation of Reed Solomon (RS) Forward Error Correcting (FEC) algorithms for the MIPS Microprocessor in several forms. The forms include varying levels of hardware complexity utilizing User Defined Instructions (UDI). Use of the UDI mechanism allows for the incorporation of digital logic to implement the array form Reed-Solomon algorithms.

### SUMMARY OF THE INVENTION

This application describes to the implementation of Reed Solomon (RS) Forward Error Correcting (FEC) algorithms for the MIPS Microprocessor in several forms. The forms include varying levels of hardware complexity utilizing User Defined Instructions (UDI). UDI instructions are recommended to support the efficient implementation of Galois Field multiplication that is typically implemented via log table look-ups, addition in log domain, anti-log table look-up of the result. Use of the UDI mechanism also allows for the incorporation of digital logic to implement the array form Reed-Solomon algorithms.

### BRIEF DESCRIPTION OF THE DRAWINGS

FIG. 1. Modulo 2 Finite Field Math

FIG. 2. GMPY4 Operation on the C64x

FIG. 3. RS Encoder Parity Generation

FIG. 4. Alternate RS Encoder Parity Generation

FIG. 5. RS Decoder Syndrome Generation

FIG. 6. Gated 2-Input XOR

FIG. 7. Galios Field Multiplier

FIG. 8. Improved Galios Field Multiplier

FIG. 9. Scalar Galios Field Multiply

FIG. 10. 4×4 SIMD Galios Field Multiply

FIG. 11. 1×4 SIMD Galios Field Multiply

FIG. 12. RS Encode Kernel

FIG. 13. RS Decode Kernel

FIG. 14. Alternate RS Decode Kernel

### DETAILED DESCRIPTION OF THE INVENTION

### 1. Background

The MIPS processor core is a 32-bit processor with efficient instructions for the implementation of many compiled and hand optimized algorithms. For the support of computationally intensive algorithms MIPS provides a mechanism for developers to incorporate special instructions into the processor core used for their specific application. The User Defined Instructions (UDI) may be specifically designed to assist with the processing of computationally intensive functions.

### 2. Introduction

This section presents a brief overview of Reed Solomon codes and their associated terminology. It also discusses the advantages of a programmable implementations of the Reed Solomon encoder and decoder.

### 2.1 Reed Solomon Codes

Reed Solomon codes are a particular case of non-binary BCH codes. They are extremely popular because of their capacity to correct burst errors. Their capacity to correct burst errors stems from the fact that they are word oriented rather than bit-oriented. A bit-oriented code such as a BCH code would treat this situation as many independent single-bit errors. To a Reed Solomon code, however a single error means any or all-incorrect bits within a single word. Therefore the RS (Reed Solomon) codes are designed to combat burst errors in a channel. In fact RS codes are a particular case of non-binary BCH codes.

The structure of a Reed Solomon code is specified by the following two parameters:
The length of the code-word m in bits, often chosen to be 8,
The number of errors to correct T.

A code-word for this code then takes the form of a block of m bit words. The number of words in the block is N, which is always equal to N=2^{m}−1 words, of which 2T words are parity or check words. For example, the m=8, t=3 RS code uses a block length of N=255 bytes, of which 6 are parity and 249 are data bytes. The number of data bytes is usually referred to by the symbol K. Thus the RS code is usually described by a compact (N,K,T) notation. (An alternative notation used is (N,K) where T is omitted as this can be simply derived as T=(N−K)/2. Both forms are used in this application.) The RS code discussed above for example has a compact notation of (255,249,3). When the number of data bytes to be protected is not close to the block length of N defined by N=2^{m}−1 words a technique called shortening is used to change the block length. A shortened RS code is one in which both the encoder and decoder agree not to use part of the allowable code space. For example, a (204,188,8) code would only use 204 of the allowable 255 code words defined by the m=8 Reed Solomon code. An error correcting code, such as an RS code, is said to be systematic if the user data to be encoded appears verbatim in the encoded code word. Thus a systematic (204,188,8) code would have the 188 data bytes provided by the user appearing verbatim in the encoded code word, appended by the 16 parity words of the encoder to form one block of 204 words. The choice of using a systematic code is merely from the point of simplicity as it lets the decoder recover the data bytes and strip off the parity bytes easily, because of the structure of the systematic code.

A programmable implementation of a RS encoder and decoder is an attractive solution as it offers the system designer the unique flexibility to trade-off the data bandwidth and the error correcting capability that is desired based on the condition of the channel. This can be done by providing the user the capability to vary the data bandwidth or the error correcting capability (T) that is required. The Texas Instruments C6400 DSP is representative of the prior art as it relates towards the implementation of RS encoders and decoders. The Texas Instruments C6400 DSP offers an instruction set that allows for the development of a high performance Reed Solomon decoder by minimizing the development time required without compromising on the flexibility that is desired. This section continues to discuss how to develop an efficient implementation of a complete (204,188,8) RS decoder solution on the Texas Instruments C6400 DSP. This Reed Solomon code was chosen as an example because it is used widely as an FEC scheme in ADSL modems.

### 2.2 Galois Fields

This section presents a brief review of the properties of Galois fields. This section presents the utmost minimum detail that is required in order to understand RS encoding and decoding. A comprehensive review of Galois fields can be obtained from references on coding theory.

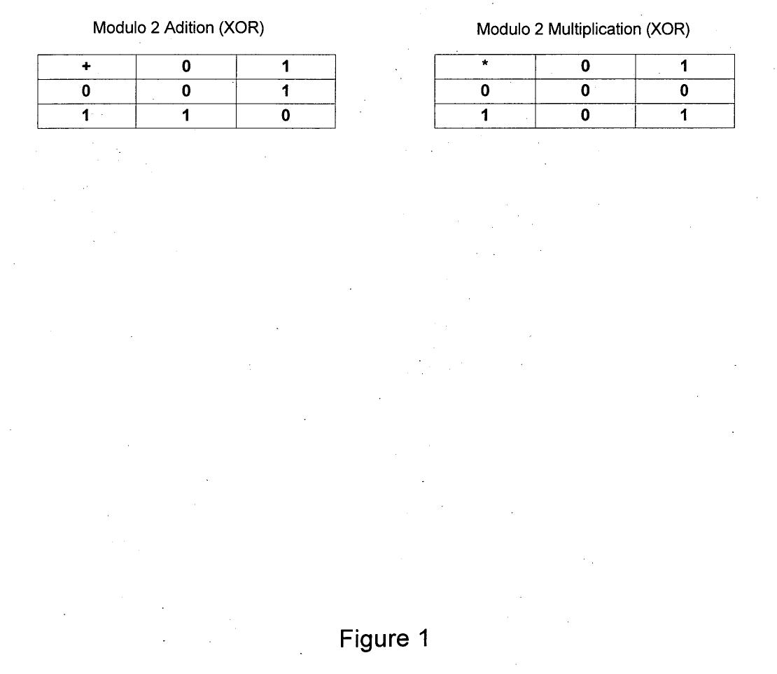

A field is a set of elements on which two binary operations can be performed. Addition and multiplication must satisfy the commutative, associative and distributive laws. A field with a finite number of elements is a finite field. Finite fields are also called Galois fields after their inventor. An example of a binary field is the set {0,1} under modulo 2 addition and modulo 2 multiplication and is denoted GF(2). The modulo 2 addition and subtraction operations are defined by the tables shown in FIG. 1. The first row and the first column indicate the inputs to the Galois field adder and multiplier. For e.g. 1+1=0 and 1*1=1.

In general if p is any prime number then it can be shown that GF(p) is a finite field with p elements and that GF(p^{m}) is an extension field with p m elements. In addition the various elements of the field can be generated as various powers of one field element α, by raising it to different powers. For example GF(256) has 256 elements which can all be generated by raising the primitive element 2 to the 256 different powers.

In addition, polynomials whose coefficients are binary belong to GF(2). A polynomial over GF(2) of degree m is said to be irreducible if it is not divisible by any polynomial over GF(2) of degree less than m but greater than zero. The polynomial F(X)=X²+X+1 is an irreducible polynomial as it is not divisible by either X or X+1. An irreducible polynomial of degree m which divides X^{2m-1}+1, is known as a primitive polynomial. For a given m, there may be more than one primitive polynomial. An example of a primitive polynomial for m=8, which is often used in most communication standards is F(X)=1+X²+X³+X⁴+X⁸.

Galois field addition is easy to implement in software, as it is the same as modulo addition. For e.g. if 29 and 16 are two elements in GF(2⁸) then their addition is done simply as an XOR operation as follows: 29 (11101) [symbol] 16(10000)=13 (01101).

Galois field multiplication on the other hand is a bit more complicated as shown by the following example, which computes all the elements of GF(2⁴), by repeated multiplication of the primitive element a. To generate the field elements for GF(2⁴) a primitive polynomial G(x) of degree m=4 is chosen as follows G(x)=1+X+X⁴. In order to make the multiplication be modulo so that the results of the multiplication are still elements of the field, any element that has the fifth bit set is brought back into a 4-bit result using the following identity F(a)=1+α+α⁴=0. This identity is used repeatedly to form the different elements of the field, by setting α⁴=1+α. Thus the elements of the field can be enumerated as follows:

{0,1,α,α²α³,1+α,α+α²,α²+α³,1+α+α³,1+α³}

Since α is the primitive element for GF(2⁴), it can be set to 2 to generate the field elements of GF(2⁴) as {0, 1, 2, 4, 8, 3, 6, 7, 12, 11 . . . 9}).

### 3. Prior Art

This section presents an overview of the Texas Instruments C6400 DSP as an example of prior art. It discusses the specific architectural enhancements that have been made to significantly increase performance for Reed Solomon encoding and decoding.

The C6400 DSP is designed for implementing Reed Solomon based error control coding because it provides hardware support for performing Galois field multiplies. In the absence of hardware to effectively perform Galois field math, previous DSP implementations made use of logarithms to perform multiplication in finite fields. This limited the performance of programmable implementations of Reed Solomon decoders on DSP architectures.

The Galois field addition is performed by the use of the XOR operation, and the multiplication operation is performed by the use of the GMPY4 instruction. The C6400 DSP allows up to 24 8-bit XOR operations to be performed in parallel every cycle. In addition it has 64 general-purpose registers that allow the architecture to obtain extremely high levels of performance. The action of the Galois field multiplier is shown in the figure below. The Galois field multiplier accepts two integers, each of which contains 4 packed bytes and multiplies them as shown below to produce four packed bytes as an integer.

C₀=B₀ [symbol] A₀, C₁=B₁ [symbol] A₁, C₂=B₂ [symbol] A₂, C₃=B₃ [symbol] A₃, where [symbol] denotes Galois field multiplication.

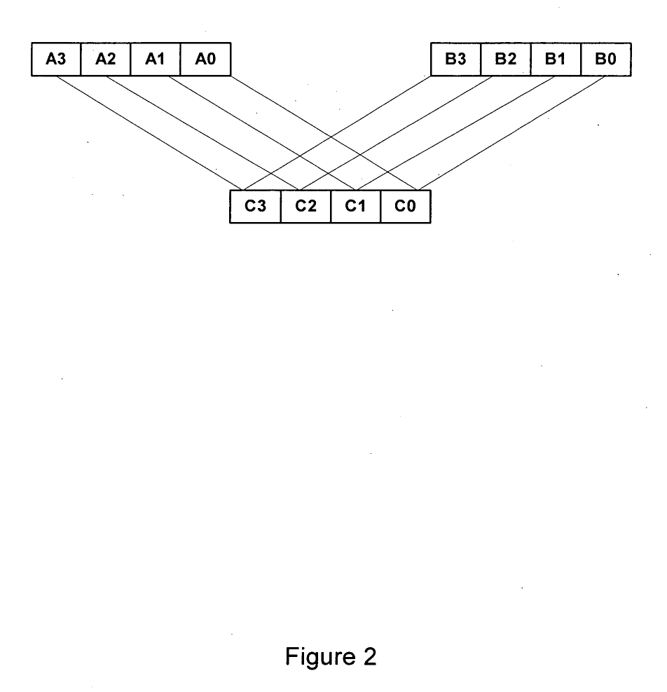

The “GMPY4” instruction denotes that all four Galois field multiplies are being performed in parallel, illustrated in FIG. 2. The architecture can issue two such GMPY4s in parallel every cycle, thus performing up to eight Galois field multiplies in parallel. This provides the architecture the capability to attain new levels of performance for Reed Solomon based coding. In addition the Galois field to be used, can be programmed using the GFPGFR register. The ability to use these instructions directly from C by the use of “intrinsics” helps to considerably reduce the software development time.

Galois field division is not used often in finite field math operations, so that it can be implemented as a look-up table if required.

Examples of Using GMPY4 for Different GF(2̂M)

The following C code fragment illustrates how the “gmpy4” instruction can be used directly from C to perform four Galois field multiplies in parallel. Previous DSPs that do not have this instruction, would typically perform the Galois field addition using logarithms. For example, two field elements a and b would be multiplied as a [symbol] b=exp[ log [a]+log [b]]. It can be seen that three lookup-table operations have to be performed for each Galois field multiply. For some computational stages of the Reed-Solomon such as syndrome accumulate and Chien search one of the inputs to the multiplier is fixed, and hence one table look up can be avoided, thereby allowing 2 Galois field multiplies every cycle. The architectural capabilities of the C6400 directly give it a 4× boost in terms of Galois field multiplier capability. The C6400 DSP allows up to eight Galois field multiplies to be performed in parallel, by the use of two gmpy4 instructions, one on each data-path. This example performs Galois field multiplies in GF(256) with the generator polynomial defined as follows: G(X) 1+X²+X³+X⁴+X⁸. The generator polynomial can be written out as a hex pattern (1+4+8+16)=29=0x1D.

The device comes up powered with the G(x) shown above as the generator polynomial for GF(256), as most communications standards make use of this polynomial for Reed Solomon based coding. If some other generator polynomial or some other GF(2^{m}) is desired then the user should initialize the GFPGFR (Galois field polynomial generator). The behavior of the GMPY4 instruction is controlled by programming the GFPGFR (Galois field polynomial generator). Two parameters are required to program the GFPGFR namely size and polynomial generator. The size field is three bits and is one smaller than the degree of the generator polynomial, in this case 8−1=7. The generator polynomial is an eight-bit field and is computed from the 8 LSBs of the hex pattern represented by 0x11D in hexadecimal. The 9th bit is always 1 for GF(256) and hence only the 8 LSBs need to be represented as the generator polynomial in the control register. The behavior of the GMPY4 instruction is controlled by programming GFPGFR (Galois field polynomial generator). Two parameters are required to program the GFPGFR namely size and polynomial generator. The size field is seven bits and is one smaller than the degree of the generator polynomial, in this case 8−1=7. The generator polynomial is an eight bit field and is computed from the eight LSBs of the hex pattern represented by 0x1D in hexadecimal. The ninth bit is always 1 for GF(256) and hence only the eight LSBs need to be represented as the generator polynomial in the control register.

### Example Showing Galois Field Multiplies on a DSP

```
inline int GMPY( int op1, int op2 )
{
/* */
/* Operands a0 and b0 are in polynomial representation. */
/* GF multiplication is in power representation. */
/* */
    int t0 = exp_table2[log_table[op1] + log_table[op2]];
    if ((op1 == 0) || (op2 == 0)) t0 = 0;
    return(t0);
}
void main( )
{
    int symbol_word0 = 0xFFCADEBA;
    int symbol_word1 = 0xABDE876E;
/* */
/* Previous DSP's would use logarithm tables to implement */
/* Galois field multiplication. */
/* */
    unsigned char byte0 = GMPY(0xBA, 0x6E);
    unsigned char byte1 = GMPY(0xDE, 0x87);
    unsigned char byte2 = GMPY(0xCA, 0xDE);
    unsigned char byte3 = GMPY(0xFF, 0xAB);
/* */
/* C6400 uses dedicated instruction accessible from C as */
/* shown below, and performs the four multiplies in */
/* parallel. */
/* symbol_word0 = 0xFFCADEBA symbol_word1 = 0xABDE876E */
/* prod_word=(0xFF *0xAB)(0xCA*0xDE)(0xDE*0x87)(0xBA*0x6E))*/
/* */
    int prod_word = _gmpy4(symbol_word0, symbol_word1);
}
```

### 4. The Reed-Solomon Forward Error Correction (FEC) Algorithm in General

A Reed-Solomon forward error correction scheme can be denoted in linear algebra terms as follows:
x=input vector where the rank (number of elements) of the vector is K and the elements are byte in size
T=number of errors the Reed-Solomon decoder can fix, there are 2T parity bytes needed for this
G=generator matrix for computing the 2T parity bytes needed
H=parity check matrix to indication if an error occur in a transmission of data

The idea behind the Reed-Solomon is the G and H are null spaces of each other.

GH^{T}=0

So if we have c=xG then cH^{T}=0. If the data c (codeword) is transmitted and received as r=c+error then rH^{T}=0 will indicate that the transmission has no errors and if rH^{T}≠0 then an error(s) occurred in the transmission.

If there is an error in the transmission, the Reed-Solomon decoder can correct up to T errors (i.e. T bytes). The Peterson-Gorenstein-Zieler method (PGZ algorithm) is used for correcting the errors in a Reed-Solomon code. After the 2T syndromes are obtained by the parity check s=rH^{T}, then an error-locator polynomial σ(x) is obtained by solving a system of t-linear equations.

$$[ \begin{matrix}{s}_{1} & {s}_{2} & … & {s}_{t} \\ {s}_{2} & {s}_{3} & … & {s}_{t + 1} \\ … & … & … & … \\ {s}_{t} & {s}_{t + 1} & … & {s}_{2 t}\end{matrix} ] [ \begin{matrix}{σ}_{t} \\ {σ}_{t - 1} \\ … \\ {σ}_{1}\end{matrix} ] = [ \begin{matrix}{s}_{t + 1} \\ {s}_{t + 2} \\ … \\ {s}_{2 t}\end{matrix} ]$$

The inverse of the v-zeros of σ(x) (error location numbers denoted X₁, . . . , X_{ν}) are then used to calculate the error magnitudes Y₁, . . . , Y_{ν}.

$$[ \begin{matrix}{X}_{1} & {X}_{2} & … & {X}_{t} \\ {X}_{1}^{2} & {X}_{2}^{2} & … & {X}_{t}^{2} \\ … & … & … & … \\ {X}_{1}^{t} & {X}_{2}^{t} & … & {X}_{t}^{t}\end{matrix} ] [ \begin{matrix}{Y}_{1} \\ {Y}_{2} \\ … \\ {Y}_{t}\end{matrix} ] = [ \begin{matrix}{s}_{1} \\ {s}_{2} \\ … \\ {s}_{t}\end{matrix} ]$$

General method for solving these sets of linear equations (such as a QR or LU factorization) are order O(t³). The matrix-vector computation is over a finite field (Galois Field) and the matrices provide great structure. To solve the first set of linear equations for the error locator polynomial σ(x), the Berlekamp-Massey algorithm is used. To solve the second set of linear equations for the error magnitudes, the Forney algorithm is used. Both of these algorithms are of order O(t²) which are an order magnitude less computational than general methods.

### 5. Reed-Solomon Encoder Implementation

The Reed-Solomon encoder is usually systematic in form which means the original vector “x” has 2T parity bytes appended to the end of it to make a codeword of length N=K+2T. The notation for a Reed-Solomon code is as RS(N,K) where 2T=N−K, so for an example a RS(255,223) code will have N=255, K=223, and T=16.

The 2T parity bytes are computed by a generator polynomial, g(X) and the coefficients of this generator polynomial are used to form G the generator matrix. In order for the generator matrix and parity matrix to be orthogonal (null space of each other) the generator polynomial is constructed as:

g(X)=(X−α)(X−α²) . . . (X−α^{2T})=g₀+g₁X+g₂X²+ . . . +g_{2T-1}X^{2T-1}+X^{2T}

or is sometimes written as

$$g ( X ) = {\prod }_{i = 0}^{2 T - 1} ( x - {α}^{( GeneratorStart + i )} )$$

The RS code is cyclic and the generator coefficients are put into a matrix as follows:

$$G = [ \begin{matrix}{g}_{0} & {g}_{1} & … & {g}_{2 T - 1} & 0 & … & 0 \\ 0 & {g}_{0} & {g}_{1} & … & {g}_{2 T - 1} & … & 0 \\ … & … & … & … & … & … & … \\ 0 & 0 & … & {g}_{0} & {g}_{1} & ⋯ & {g}_{2 T - 1}\end{matrix} ] now c = xG$$

Computing a cyclic matrix above can be implemented as an LFSR with GF(2̂8) math operators. Typically C-code for a RS(N,K) encoder is given below:

```
for (i = 0; i < K; i++) { // K = 223
    feedback = LOG[data[i] \hat{ } crc[0]];
    // Perform the GF multiplication for the 2T parity elements of the
    LFSR
    if (feedback != A0) { // feedback term is non-zero
        for (j = 1; j < 2*T; j++) { // 2T = 32
            crc[j] \hat{ }= ANTI_LOG[feedback + ALPHA[j−1]];
        }
    }
    // Shift remember that this is a cyclical code
    memmove (&crc[0], &crc[1], sizeof (unsigned char) * (2*T−1));
    if (feedback != A0) {
        crc[2*T−1] = ANTI_LOG[feedback + ALPHA[2*T−1]];
    } else {
            crc[2*T−1] = 0;
        }
    }
```

Note: use of the modulo function, MODNN( ), is omitted for clarity of the code examples but is required after each arithmetic addition.

### 5.1 Software Only Implementation

The Reed Solomon FEC scheme is dominated computationally by multiplication over a finite field (Galois Field multiplication). Without a GF instruction, the multiplication is performed by addition in the log domain as follows:

```
// ANTI_LOG is a 512 element table of bytes
// LOG is a 256 element table of bytes
byte GF_MULT (byte x, byte y)
{
  if ((x == 0) || (y == 0)) {
    return 0;
  } else {
    return ANTI_LOG[LOG[x]+LOG[y]];
  }
}
```

The above GF multiplication requires two checks with zeros and three byte table look-ups. With a Reed Solomon FEC structure, the multiplications are performed over constants (such as generator polynomial coefficients, powers of the primitive element) which introduces constraints to the GF multiplication reducing the complexity. For example, with the RS encoder the generation of the parity bytes (done by a LFSR) is written as follows:

```
for (i = 0; i < K; i++) { // K = 223
  feedback = LOG[data[i] \hat{ } crc[0]];
  // Perform the GF multiplication for the 2T parity elements of the LFSR
  if (feedback != A0) { // feedback term is non-zero
    for (j = 1; j < 2*T; j++) { // 2T = 32
      crc[j] \hat{ }= ANTI_LOG[feedback + ALPHA[j−1]];
    }
  }
  // Shift remember that this is a cyclical code
  memmove (&crc[0], &crc[1], sizeof (unsigned char) * (2*T−1));
  if (feedback != A0) {
    crc[2*T−1] = ANTI_LOG[feedback + ALPHA[2*T−1]];
  } else {
    crc[2*T−1] = 0;
  }
}
```

Since the coefficients of the generator polynomial are not zero, this eliminates one check with zero and the coefficients are left in LOG form to reduce one table look-up. Thus, the GF multiplication for the encoder can be performed by one table look-up, and add, and a check for zero every, 2T multiplies. This is the easiest GF multiplication in a Reed-Solomon scheme.

### 5.2 Scalar GF Hardware Implementation

With a hardware GF_MULT_SCALAR instruction, the above code can be written as follows:

```
for (i = 0; i < K; i++) { // K = 223
  feedback = data[i] \hat{ } crc[0];
  // Perform the GF multiplication for the 2T parity elements of the LFSR
  for (j = 1; j < 2*T; j++) { // 2T = 32
    crc[j] \hat{ }= GF_MULT_SCALAR (feedback, ALPHA[j−1]);
  }
  // Shift remember that this is a cyclical code
  memmove (&crc[0], &crc[1], sizeof (unsigned char) * (2*T−1));
  crc[*2T−1] = GF_MULT_SCALAR (feedback, ALPHA[2*T−1]);
}
```

The GF_MULT_SCALAR instruction for the encoder will be issued 2T*K times replacing the original:

1) (2T+1)*K table look-ups

2) K checks with zeros

3) 2T*K adds

### 5.3 SIMD GF Multiply Implementation

The inner loop can be unrolled four times (as follows) which demonstrates how a GF_MULT_SIMD multiplication can be developed and implemented.

```
for (i = 0; i < K; i++) { // K = 223
  crc[2*T] = 0;
  feedback = data[i] \hat{ } crc[0];
  // Perform the GF multiplication for the 2T parity elements of the LFSR
  for (j = 0; j < 2*T; j += 4) { // 2T = 32
    crc[j+1] \hat{ }= GF_MULT_SCALAR_1_4 (feedback, ALPHA[j]);
    crc[j+2] \hat{ }= GF_MULT_SCALAR_1_4 (feedback, ALPHA[j+1]);
    crc[j+3] \hat{ }= GF_MULT_SCALAR_1_4 (feedback, ALPHA[j+2]);
    crc[j+4] \hat{ }= GF_MULT_SCALAR_1_4 (feedback, ALPHA[j+3]);
  }
  // Shift remember that this is a cyclical code
  memmove (&crc[0], &crc[1], sizeof (unsigned char) * (2*T));
}
```

With a Single Instruction Multiple Data (SIMD) instruction operating on 32 bits at a time, the above code can be written as follows:

```
for (i = 0; i < K; i++) { // K = 223
  crc[2*T] = 0;
  feedback = data[i] \hat{ } crc[0];
  // Perform the GF multiplication for the 2T parity elements of the LFSR
  for (j = 0; j < 2*T/4; j ++) { // 2T = 32
    int *crc_p = (int *) &crc[j*4+1];
    *crc_p \hat{ }= GF_MULT_SIMD_1_4 (feedback, &ALPHA[j*4]);
  }
  // Shift remember that this is a cyclical code
  memmove (&crc[0], &crc[1], sizeof (unsigned char) * (2*T));
}
```

Note, crc_p is referencing the crc byte parity array as 32 bit integers. The inner loop initial value is changed to be “j=0” thereby eliminating the last GF_MULT_SCALAR. The array crc is extended by 1 byte and the memory move copies the result of the equivalent last GF_MULT_SCALAR. This implementation uses an instruction similar what is available on a Texas Instruments C6400 DSP which is representative of the prior art. The next section describes the enhancements unique to this application.

The GF_MULT_SIMD instruction for the encoder will be issued 2T/4*K times replacing:

1) (2T+1)*K table look-ups

2) K checks with zeros

3) 2T*K adds

Example:

Using the RS(255,223) code without a GF instruction requires:

1) (2T+1)*K table look-ups=33*223=7359 table look-ups

2) K checks with zeros=223 check with zeros

3) 2T*K adds=23*223=5359 adds

Totaling ˜12941 instructions issued.

The RS(255,223) code with a GF_MULT_SIMD instruction requires (2T/4)*K=8*223=1784 instructions issued.

### 5.4 RS Encode Kernel Implementation

In a preferred embodiment, the RS encoder algorithms may be further transformed to exploit independence between the effect of four successive feedback terms and all but three parity bytes. The first 3 feedback terms are applied to the first few parity bytes sequentially (3 for the first feedback, 2 for the second and 1 for the third). The fourth feedback term is computed and then all four feedback terms may be used for the following 32 parity bytes. The preferred embodiment provides a RS_ENCODE_KERNEL instruction which performs 16 GF multiplications using the 4 feedback terms and updated 4 parity bytes in a single (pipelined) instruction. The generator polynomial coefficients should be delivered by a ROM to each specific Galois Field multiplier since these are constant for each element of the kernel.

The RS encoder algorithms need no special re-organization to exploit the RS_ENCODE_KERNEL instruction as four parity bytes may be processed concurrently. The only difference would be additional generator polynomial coefficients delivered from the ROM. The outer loop can be unrolled four times (as follows) which demonstrates how a RS_ENCODE_KERNEL multiplication can be developed and implemented.

```
for (i = 0; i < K−4; i += 4) { // K = 223
  crc[2*T] = 0;
  crc[2*T+1] = 0;
  crc[2*T+2] = 0;
  crc[2*T+3] = 0;
  fb[0] = data[i] \hat{ } crc[0];
  crc[1] \hat{ }= GF_MULT_SCALAR (fb[0], ALPHA[0]);
  crc[2] \hat{ }= GF_MULT_SCALAR (fb[0], ALPHA[1]);
  crc[3] \hat{ }= GF_MULT_SCALAR (fb[0], ALPHA[2]);
  fb[1] = data[i+1] \hat{ } crc[1];
  crc[2] \hat{ }= GF_MULT_SCALAR (fb[1], ALPHA[0]);
  crc[3] \hat{ }= GF_MULT_SCALAR (fb[1], ALPHA[1]);
  fb[2] = data[i+2] \hat{ } crc[2];
  crc[3] \hat{ }= GF_MULT_SCALAR (fb[2], ALPHA[0]);
  fb[3] = data[i+3] \hat{ } crc[3];
  // Perform the GF multiplication for the 2T parity elements of the LFSR
  for (j = 0; j < 2*T/4−1; j ++) { // 2T = 32
    int *crc_p = (int *) &crc[j*4+4];
    *crc_p \hat{ }= GF_MULT_SIMD_1_4 (fb[0], &ALPHA[j*4+3]);
    *crc_p \hat{ }= GF_MULT_SIMD_1_4 (fb[1], &ALPHA[j*4+2]);
    *crc_p \hat{ }= GF_MULT_SIMD_1_4 (fb[2], &ALPHA[j*4+1]);
    *crc_p \hat{ }= GF_MULT_SIMD_1_4 (fb[3], &ALPHA[j*4]);
  }
  crc[32] \hat{ }= GF_MULT_SCALAR (fb[0], ALPHA[31]);
  crc[32] \hat{ }= GF_MULT_SCALAR (fb[1], ALPHA[30]);
  crc[33] \hat{ }= GF_MULT_SCALAR (fb[1], ALPHA[31]);
  crc[32] \hat{ }= GF_MULT_SCALAR (fb[2], ALPHA[29]);
  crc[33] \hat{ }= GF_MULT_SCALAR (fb[2], ALPHA[30]);
  crc[34] \hat{ }= GF_MULT_SCALAR (fb[2], ALPHA[31]);
  crc[32] \hat{ }= GF_MULT_SCALAR (fb[3], ALPHA[28]);
  crc[33] \hat{ }= GF_MULT_SCALAR (fb[3], ALPHA[29]);
  crc[34] \hat{ }= GF_MULT_SCALAR (fb[3], ALPHA[30]);
  crc[35] \hat{ }= GF_MULT_SCALAR (fb[3], ALPHA[31]);
  // Shift remember that this is a cyclical code
  memmove (&crc[0], &crc[4], sizeof (unsigned char) * (2*T));
}
```

With a Reed Solomon Encode Kernel instruction operating on four feedback terms and four parity bytes at a time (optimized for 32 bits each), the above code can be written as follows:

```
for (i = 0; i < K−4; i += 4) { // K = 223
  crc[2*T] = 0;
  crc[2*T+1] = 0;
  crc[2*T+2] = 0;
  crc[2*T+3] = 0;
  fb[0] = data[i] \hat{ } crc[0];
  crc[1] \hat{ }= GF_MULT_SCALAR (fb[0], ALPHA[0]);
  crc[2] \hat{ }= GF_MULT_SCALAR (fb[0], ALPHA[1]);
  crc[3] \hat{ }= GF_MULT_SCALAR (fb[0], ALPHA[2]);
  fb[1] = data[i+1] \hat{ } crc[1];
  crc[2] \hat{ }= GF_MULT_SCALAR (fb[1], ALPHA[0]);
  crc[3] \hat{ }= GF_MULT_SCALAR (fb[1], ALPHA[1]);
  fb[2] = data[i+2] \hat{ } crc[2];
  crc[3] \hat{ }= GF_MULT_SCALAR (fb[2], ALPHA[0]);
  fb[3] = data[i+3] \hat{ } crc[3];
  // Perform the GF multiplication for the 2T parity elements of the LFSR
  for (j = 0; j < 2*T/4−1; j ++) { // 2T = 32
    int *crc_p = (int *) &crc[j*4+4];
    *crc_p \hat{ }= RS_ENCODE_KERNEL (fb, &ALPHA[j*4]);
  }
  crc[32] \hat{ }= GF_MULT_SCALAR (fb[0], ALPHA[31]);
  crc[32] \hat{ }= GF_MULT_SCALAR (fb[1], ALPHA[30]);
  crc[33] \hat{ }= GF_MULT_SCALAR (fb[1], ALPHA[31]);
  crc[32] \hat{ }= GF_MULT_SCALAR (fb[2], ALPHA[29]);
  crc[33] \hat{ }= GF_MULT_SCALAR (fb[2], ALPHA[30]);
  crc[34] \hat{ }= GF_MULT_SCALAR (fb[2], ALPHA[31]);
  crc[32] \hat{ }= GF_MULT_SCALAR (fb[3], ALPHA[28]);
  crc[33] \hat{ }= GF_MULT_SCALAR (fb[3], ALPHA[29]);
  crc[34] \hat{ }= GF_MULT_SCALAR (fb[3], ALPHA[30]);
  crc[35] \hat{ }= GF_MULT_SCALAR (fb[3], ALPHA[31]);
  // Shift remember that this is a cyclical code
  memmove (&crc[0], &crc[4], sizeof (unsigned char) * (2*T));
}
Note:
crc_p is again referencing the crc byte parity array as 32 bit integers. The inner loop termination is now changed to be “j ≦ 2T/4−1” thereby eliminating the last GF_MULT_SCALAR. Also, the size of the crc array is increased by 4 elements to accommodate the RS_ENCODE_KERNEL processing of four feedback bytes concurrently.
```

The set of ALPHA constants may be obtained from a ROM index by the value of “i”. Seven different constants are provided to the array of sixteen Galios Field multipliers operating on the fb[i] bytes. A uniform implementation would duplicate the constants in a ROM to provide each Galios Field multiplier with its appropriate constant operand.

The RS_ENCODE_KERNEL instruction for the encoder will be issued (2T/4−1)*K/4 times replacing:

1) (2T+1)*K table look-ups

2) K checks with zeros

3) 2T*K adds

Example:

Using the RS(255,223) code without a GF instruction requires:

1) (2T+1)*K table look-ups=33*223=7359 table look-ups

2) K checks with zeros=223 check with zeros

3) 2T*K adds=23*223=5359 adds

Totaling ˜12941 instructions issued.

The RS(255,223) code with a RS_ENCODE_KERNEL instruction requires (2T/4)*K/4=8*223/4=440 instructions issued. (Note: completion of the remainder of 223/4 data bytes requires a few more processing steps and is not shown in the example implementation.)

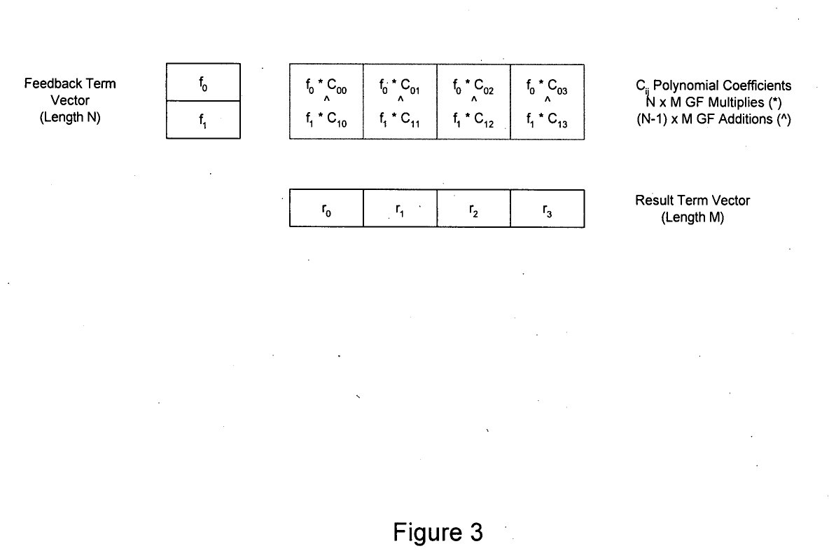

In a preferred embodiment illustrated in FIG. 3, the parallelized method used in the generation of Reed Solomon parity bytes utilizes multiple digital logic operations or computer instructions implemented using digital logic. At least one of the operations or instructions used performs the following combinations of steps: a) provide an operand representing N feedback terms where N is greater than one, b) computation of N by M Galios Field polynomial multiplications where M is greater than one, and c) computation of (N−1) by M Galios Field additions producing M result bytes. In this case the result bytes are used to modify the Reed Solomon parity bytes in either a separate operation or instruction or as part of the same operation.

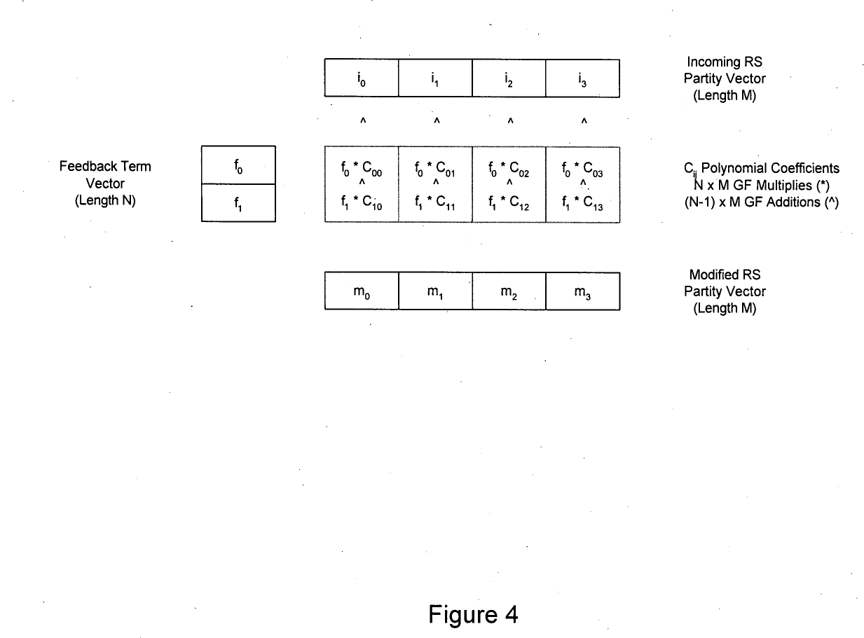

In another preferred embodiment illustrated in FIG. 4, the parallelized method used in the generation of Reed Solomon parity bytes utilizes multiple digital logic operations or computer instructions implemented using digital logic. At least one of the operations or instructions performs the following combinations of steps: a) provide an operand representing N feedback terms where N is greater than one, b) provide an operand representing M incoming Reed Solomon parity bytes where M is greater than one, c) computation of N by M Galios Field polynomial multiplications, d) computation of N by M Galios Field additions producing M modified Reed Solomon parity bytes.

In both of the aforementioned preferred embodiments, the values of N and M as shown in the figures are two and four respectively. In the preceding code examples, the values of N and M were selected to be four as this matched the word width of the MIPS microprocessor. When N and M are both the value of four, sixteen Galios Field polynomial multiplications are computed concurrently or sequentially in a pipeline. Each Galios Field polynomial multiplication utilizes a coefficient delivered from a memory device, which in a preferred embodiment, would be implemented either by a read only memory (ROM), random access memory (RAM) or a register file. The generation of Reed Solomon parity bytes requires several iterations each time using previous modified Reed Solomon parity bytes as incoming Reed Solomon parity bytes.

### 5.5 RS Encode Kernel Further Improved

The Reed Solomon Encode Kernel may be further improved by exploiting SIMD processing for the beginning and ending portions of the outer loop.

The code used at the beginning of the outer loop is shown below:

fb[0] = data[i] \hat{ } crc[0];
crc[1] \hat{ }= GF_MULT_SCALAR (fb[0], ALPHA[0]);
crc[2] \hat{ }= GF_MULT_SCALAR (fb[0], ALPHA[1]);
crc[3] \hat{ }= GF_MULT_SCALAR (fb[0], ALPHA[2]);

The ALPHA coefficient array may be pre-pended with additional coefficients of zero before the beginning thereby not affecting the corresponding CRC byte. The code becomes the following:

fb[0] = data[i] \hat{ } crc[0];
crc[0] \hat{ }= GF_MULT_SCALAR (fb[0], 0);
crc[1] \hat{ }= GF_MULT_SCALAR (fb[0], ALPHA[0]);
crc[2] \hat{ }= GF_MULT_SCALAR (fb[0], ALPHA[1]);
crc[3] \hat{ }= GF_MULT_SCALAR (fb[0], ALPHA[2]);

This may be further replaced by the SIMD instruction and ALPHA[−1] being a pre-pended zero coefficient:

int *crc_p = (int *) &crc[0];
fb[0] = data[i] \hat{ } crc[0];
*crc_p \hat{ }= GF_MULT_SIMD_1_4 (fb[0], &ALPHA[−1]);

The code used at the end of the outer loop is shown below:

crc[32] \hat{ }= GF_MULT_SCALAR (fb[0], ALPHA[31]);
crc[32] \hat{ }= GF_MULT_SCALAR (fb[1], ALPHA[30]);
crc[33] \hat{ }= GF_MULT_SCALAR (fb[1], ALPHA[31]);
crc[32] \hat{ }= GF_MULT_SCALAR (fb[2], ALPHA[29]);
crc[33] \hat{ }= GF_MULT_SCALAR (fb[2], ALPHA[30]);
crc[34] \hat{ }= GF_MULT_SCALAR (fb[2], ALPHA[31]);
crc[32] \hat{ }= GF_MULT_SCALAR (fb[3], ALPHA[28]);
crc[33] \hat{ }= GF_MULT_SCALAR (fb[3], ALPHA[29]);
crc[34] \hat{ }= GF_MULT_SCALAR (fb[3], ALPHA[30]);
crc[35] \hat{ }= GF_MULT_SCALAR (fb[3], ALPHA[31]);

The ALPHA coefficient array may be appended with additional coefficients of zero at the end thereby not affecting the corresponding CRC byte. The code becomes the following:

crc[32] \hat{ }= GF_MULT_SCALAR (fb[0], ALPHA[31]);
crc[33] \hat{ }= GF_MULT_SCALAR (fb[0], 0);
crc[34] \hat{ }= GF_MULT_SCALAR (fb[0], 0);
crc[35] \hat{ }= GF_MULT_SCALAR (fb[0], 0);
crc[32] \hat{ }= GF_MULT_SCALAR (fb[1], ALPHA[30]);
crc[33] \hat{ }= GF_MULT_SCALAR (fb[1], ALPHA[31]);
crc[34] \hat{ }= GF_MULT_SCALAR (fb[1], 0);
crc[35] \hat{ }= GF_MULT_SCALAR (fb[1], 0);
crc[32] \hat{ }= GF_MULT_SCALAR (fb[2], ALPHA[29]);
crc[33] \hat{ }= GF_MULT_SCALAR (fb[2], ALPHA[30]);
crc[34] \hat{ }= GF_MULT_SCALAR (fb[2], ALPHA[31]);
crc[35] \hat{ }= GF_MULT_SCALAR (fb[2], 0);
crc[32] \hat{ }= GF_MULT_SCALAR (fb[3], ALPHA[28]);
crc[33] \hat{ }= GF_MULT_SCALAR (fb[3], ALPHA[29]);
crc[34] \hat{ }= GF_MULT_SCALAR (fb[3], ALPHA[30]);
crc[35] \hat{ }= GF_MULT_SCALAR (fb[3], ALPHA[31]);

This may be further replaced by the KERNEL instruction and ALPHA[32], ALPHA[33] and ALPHA[34] being a pre-pended zero coefficients:

int *crc_p = (int *) &crc[32];
*crc_p \hat{ }= RS_ENCODE_KERNEL (fb, &ALPHA[32]);

This is simply extending the inner loop by one iteration and eliminating the entire special ending code used as part of the outer loop.

### 5.6 Reed Solomon Encode Performance on the MIPS Processor

Using the popular RS(255,223) coder as an example, the following table summarizes the MIPS required per megabit of user data and the approximate gate count for each of the recommended implementations:

| | Encode | Gates | ROM |
|---|---|---|---|
| Optimized MIPS Assembly | 39.9 | none | none |
| Scalar GF Multiply Support | 12.9 | 600 | none |
| SIMD GF Multiply Support | 2.2 | 1560 | 4 × 32 bytes |
| RS Encode Kernel Support | 1.05 | 6240 | 1024 bytes |

Each of these UDI implementations is a simple hardware block with no buried state information simplifying context switching. ROM (or RAM) space is required to provide the various polynomial coefficients used by the Galois Field instructions. Additional ROM (or RAM) entries are needed for different RS coders.

Note: Additional optimization by elimination of memory copying and use of register variables was not shown but is assumed to provide the performance numbers given above. Also, the optimization shown in the previous section extending either the data and/or coefficient array is also possible with other suggested implementations. These improvements would be obvious to one skilled in the art along with this teaching and is not explicitly shown in this specification. The MIPS projections given in the tables below assume all of these optimizations are exploited.

### 6. Reed-Solomon Decoder

The RS decoder can be broken into 4 steps which are, syndrome calculation, generation of error location polynomial (Berlekamp-Massey algorithm), search for roots of the error location polynomial (Chien Search algorithm), and generation of error magnitudes (Forney algorithm). With a large block size, such as for a RS(255,223) code, the syndrome calculation is the most computationally intensive. The syndromes have to be calculated for every decoded block and if the syndromes are not all zero, an error occurred which requires the additional three algorithms (BK-Massey, Chien and Forney).

### 6.1 Syndrome/Check Calculation

The parity check by a matrix-vector multiplication with H and x. The resulting vector's (rank 2T) elements are called the syndromes and they should all be equal to zero if an error is not present.

$$\begin{matrix}{s}_{1 , 2 T} = {rH}^{T} \\ = [ \begin{matrix}{r}_{0} & {r}_{1} & {r}_{2}\end{matrix} … {r}_{n - 1} ] \\ {[ \begin{matrix}1 & 1 & 1 & … & 1 \\ α & {α}^{2} & {α}^{3} & … & {α}^{2 T} \\ {α}^{2} & {( {α}^{2} )}^{2} & {( {α}^{3} )}^{2} & … & {( {α}^{2 T} )}^{2} \\ … & … & … & … & \\ {α}^{N - 1} & {( {α}^{2} )}^{N - 1} & {( {α}^{3} )}^{N - 1} & … & {( {α}^{2 T} )}^{N - 1}\end{matrix} ]}_{N , 2 T} \\ = [ \begin{matrix}{s}_{0} & {s}_{1} & {s}_{2} & … & {s}_{2 T - 1}\end{matrix} ]\end{matrix}$$

Although one could perform standard matrix-vector multiplication to calculate the syndromes, the matrix H^{T} is a Vandermonde matrix and one can use Horner's rule to calculate the matrix-vector multiplication. By using Horner's rule, only 2*T elements have to be stored in memory as opposed to N*2T elements for the standard matrix-vector multiplication.

Horner's rule is a recursive way of solving polynomials and an example is:

1+x+x²+x³+x⁴=(x(x(x(x+1)+1)+1)+1

Typical c-code for solving the syndromes for a Reed-Solomon code is as follows:

### 6.1.1 Optimized Software

The calculation of the syndrome is given below:

```
// s[2T] is the syndrome
for (j = 1; j < N; j++) {
  for (i = 0; i < 2*T; i++) {
    if (s[i] == 0) {
      s[i] = data[j];
    } else {
      s[i] = data[j] \hat{ } ANTI_LOG[MODNN (LOG[s[i]] +
      (FCR+i)*PRIM)];
    }
  }
}
```

There are (N*2T) GF multiplications and each GF multiplication requires:

1) Check with zero

2) LOG table look-up

3) ANTI_LOG table look-up

4) Add

5) Possible MODNN table look-up depending on the RS code (we will leave this out for comparisons)

The GF multiplication avoids one table look-up and one check for zero because the syndromes are calculated using the powers of the primitive element (primitive element=2) which are left in LOG format.

### 6.1.2 Scalar GF Hardware

If a GF multiplication is introduced, the syndrome calculation is as follows:

```
for (j = 1; j < N; j++) {
  for (i = 0; i < 2T; i++) {
    s[i] = data[j] \hat{ } GF_MULT_SCALAR (s[i], BETA[i]);
  }
}
```

The GF_MULT_SCALAR instruction replaces 2 table look-ups, a check for zero, and an add from the original code.

### 6.1.3 SIMD GF Multiply

Since most processors are 32-bit, 4 of the GF_MULT_SCALAR instructions can be done in parallel (like a SIMD add of 4 bytes with a 32-bit processor). The inner loop of the previous code can be unrolled to obtain the following:

```
for (j = 1; j < N; j++) {
  for (i = 0; i < 2*T; i +=4) {
    // One SIMD instruction will do the 4 instructions below
    s[i] = GF_MULT_SCALAR (s[i], BETA[i]);
    s[i+1] = GF_MULT_SCALAR (s[i+1], BETA[i+1]);
    s[i+2] = GF_MULT_SCALAR (s[i+2], BETA[i+2]);
    s[i+3] = GF_MULT_SCALAR (s[i+3], BETA[i+3]);
    // One SIMD XOR instruction for the 4 XORS below
    s[i] = data[j] \hat{ } s[i];
    s[i+1] = data[j] \hat{ } s[i+1];
    s[i+2] = data[j] \hat{ } s[i+2];
    s[i+3] = data[j] \hat{ } s[i+3];
  }
}
```

With a GF_MULT_SIMD instruction, the above code can be written as follows:

```
for (j = 1; j < N; j++) {
  for (i = 0; i < 2*T; i += 4) {
    int *s_p = (int *) &s[i];
    *s_p = GF_MULT_SIMD_4_4 (&s[i], &BETA[i]);
    *s_p = XOR_SIMD_1_4 (data[j], &s[i]);
  }
}
```

Note, s_p is referencing the s byte parity array as 32 bit integers. This form of SIMD instruction (denoted as GF_MULT_SIMD_{—}4_{—}4), uses four bytes of the syndrome word operand (denoted in bytes as s[i], s[i+1], s[i+2] and s[i+3]) and four bytes of the BETA constant word operand (denoted in bytes as BETA[i], BETA[i+1], BETA[i+2] and BETA[i+3]). The form of SIMD instruction previously used and denoted as GF_MULT_SIMD_{—}4_{—}4), uses a common byte of the feedback operand (commonly denoted as fb) and four bytes of the ALPHA constant word operand (denoted in bytes as ALPHA[i], ALPHA[i+1], ALPHA[i+2] and ALPHA[i+3]). This implementation again uses an instruction similar what is available on a Texas Instruments C6400 DSP which is representative of the prior art. The next section describes the enhancements unique to this application.

The GF_MULT_SIMD instruction replaces 8 table-look-ups, 4 checks with zeros, and 4 adds for the syndrome calculation.

For a RS(N,K) syndrome calculation, (2T/4)*N GF_MULT_SIMD instructions replaces:

1) N*2T*2=4TN table look-ups

2) 2TN checks with zero

3) 2TN adds

Example:

The RS(255,223) code without a GF instruction requires:

1) 2*32*255=16320 table look-ups

2) 32*255=8160 checks with zeros

3) 32*255=8160 adds

Totaling ˜32640 instructions to issue.

The RS(255,223) code with a GF_MULT_SIMD instruction requires:

1) N*(2T/4)=255*32/4=2040 GF_MULT_SIMD instructions
Again the GF_MULT_SIMD instruction greatly reduces the number of instructions issued from 32.640 to 2040 which is a factor of ˜16.

### 6.1.4 RS Decode Kernel

In a preferred embodiment, the RS decoder algorithms may be further transformed to exploit independence not readily apparent. If we unroll the loop four times we have the following:

```
for (j = 1; j < (N−4); j += 4) {
  for (i = 0; i < 2*T; i += 4) {
    int *s_p = (int *) &s[i];
    *s_p = GF_MULT_SIMD_4_4 (&s[i], &BETA[i]);
    *s_p = XOR_SIMD_1_4 (data[j], &s[i]);
    *s_p = GF_MULT_SIMD_4_4 (&s[i], &BETA[i]);
    *s_p = XOR_SIMD_1_4 (data[j+1], &s[i]);
    *s_p = GF_MULT_SIMD_4_4 (&s[i], &BETA[i]);
    *s_p = XOR_SIMD_1_4 (data[j+2], &s[i]);
    *s_p = GF_MULT_SIMD_4_4 (&s[i], &BETA[i]);
    *s_p = XOR_SIMD_1_4 (data[j+3], &s[i]);
  }
}
// Process remaining 2 data/crc bytes
j = 253; // last iteration, j = 249. j+3 = 252
for (i = 0; i < 2*T; i++) {
  s[i] = data[j] \hat{ } GF_MULT_SCALAR (s[i], BETA[i]);
  s[i] = data[j+1] \hat{ } GF_MULT_SCALAR (s[i], BETA[i]);
}
```

The inner loop may be replaced with a KERNEL performing the above processing as follows:

```
for (j = 1; j < (N−4); j += 4) {
    for (i = 0; i < 2*T; i += 4) {
        int *s_p = (int *) &s[i];
        int *d_p = (int *) &data[j];
        *s_p = RS_DECODE_KERNEL (*d_p, *s_p, &BETA[i]);
    }
}
// Process remaining 2 data/crc bytes
j = 253; // last iteration, j = 249. j+3 = 252
for (i = 0; i < 2*T; i++) {
    s[i] = data[j] \hat{ } GF_MULT_SCALAR (s[i], BETA[i]);
    s[i] = data[j+1] \hat{ } GF_MULT_SCALAR (s[i], BETA[i]);
}
```

The kernel instruction operates on four syndrome bytes and four data bytes in the sequence illustrated by the previous code example. A minor disadvantage of this kernel is the sequential steps of Galios Field multiplications and Galios Field additions (exclusive ors). An alternate implementation of a kernel is inspired by examining the effective processing for each syndrome byte:

s[i] = gf_mult (s[i], BETA[i]);
s[i] = data[j] \hat{ } s[i];
s[i] = gf_mult (s[i], BETA[i]);
s[i] = data[j+1] \hat{ } s[i];
s[i] = gf_mult (s[i], BETA[i]);
s[i] = data[j+2] \hat{ } s[i];
s[i] = gf_mult (s[i], BETA[i]);
s[i] = data[j+3] \hat{ } s[i];

This may be expanded by expanding s[i] in each equation working from the bottom upward to get the following equation:

```
s[i] = data[j+3] \hat{ } gf_mult (data[j+2] \hat{ } gf_mult
                (data[j+1] \hat{ } gf_mult (data[j] \hat{ } gf_mult (s[i],
                BETA[i]), BETA[i]), BETA[i]), BETA[i]);
```

This may be re-written by using the distributive and associative properties of Galios Field operations to be the following:

a \hat{ } gf_mult (b, c) ≡ gf_mult (a, b) \hat{ } gf_mult (a, c)
a \hat{ } (b \hat{ } c) ≡ (a \hat{ } b) \hat{ } c
gf_mult (a, gf_mult (b, c)) ≡ gf_mult(gf_mult (a, b), c)

For reference the standard arithmetic distributive and associative properties are:

a + b * c ≡ a * b + a * c
a + (b + c) ≡ (a + b) + c
a * (b * c) ≡ (a * b) * c

The following equation results from the use of the distributive and associative properties:

```
s[i] = data[j+3] \hat{ } gf_mult (data[j+2], BETA[i]) \hat{ }
                gf_mult (gf_mult (data[j+1], BETA[i]), BETA[i]) \hat{ }
                gf_mult (gf_mult (gf_mult (data[j], BETA[i]),
                BETA[i]), BETA[i]) \hat{ }
                gf_mult (gf_mult (gf_mult (gf_mult (s[i], BETA[i]),
                BETA[i]), BETA[i]), BETA[i]);
```

The nested Galios Field multiplications by the constant BETA[i] may be computed in an alternate order as the associative property applies to Galios Field operations. The code becomes:

```
s[i] = data[j+3] \hat{ } gf_mult (data[j+2], BETA[i]) \hat{ }
                gf_mult (data[j+1], gf_mult (BETA[i],
                BETA[i])) \hat{ }
                gf_mult (data[j], gf_mult (gf_mult (BETA[i],
                BETA[i]), BETA[i])) \hat{ }
                gf_mult (s[i], gf_mult (gf_mult (gf_mult (BETA[i],
                BETA[i]), BETA[i]), BETA[i]));
```

And the constant multiplications may be precomputed as “powers” of BETA denoted as

BETA2[i] = gf_mult (BETA[i], BETA[i]);
BETA3[i] = gf_mult (gf_mult (BETA[i], BETA[i]), BETA[i]);
BETA4[i] = gf_mult (gf_mult (gf_mult (BETA[i], BETA[i]),
BETA[i]), BETA[i]);

Finally, the processing for each syndrome byte becomes:

```
s[i] = data[j+3] \hat{ } gf_mult (data[j+2], BETA[i]) \hat{ }
                gf_mult (data[j+1], BETA2[i]) \hat{ }
                gf_mult (data[j], BETA3[i]) \hat{ }
                gf_mult (s[i], BETA4[i]);
```

When processing 4 syndrome bytes in parallel, the operation performed is:

```
s[i] = data[j+3] \hat{ } gf_mult (data[j+2], BETA[i]) \hat{ }
                gf_mult (data[j+1], BETA2[i]) \hat{ }
                gf_mult (data[j], BETA3[i]) \hat{ }
                gf_mult (s[i], BETA4[i]);
s[i+1] = data[j+3] \hat{ } gf_mult (data[j+2], BETA[i+1]) \hat{ }
                gf_mult (data[j+1], BETA2[i+1]) \hat{ }
                gf_mult (data[j], BETA3[i+1]) \hat{ }
                gf_mult (s[i+1], BETA4[i+1]);
s[i+2] = data[j+3] \hat{ } gf_mult (data[j+2], BETA[i+2]) \hat{ }
                gf_mult (data[j+1], BETA2[i+2]) \hat{ }
                gf_mult (data[j], BETA3[i+2]) \hat{ }
                gf_mult (s[i+2], BETA4[i+2]);
s[i+3] = data[j+3] \hat{ } gf_mult (data[j+2], BETA[i+3]) \hat{ }
                gf_mult (data[j+1], BETA2[i+3]) \hat{ }
                gf_mult (data[j], BETA3[i+3]) \hat{ }
                gf_mult (s[i+3], BETA4[i+3]);
```

This processing may be represented by the following code using the Galios Field SIMD instructions (please see the description of GF_MULT_SIMD_{—}4_{—}4 and GF_MULT_SIMD_{—}1_{—}4 in the previous section):

```
for (j = 1; j < (N−4); j += 4) {
    for (i = 0; i < 2*T; i += 4) {
        int *s_p = (int *) &s[i];
        *s_p = GF_MULT_SIMD_4_4 (&s[i], &BETA4[i]);
        *s_p \hat{ }= GF_MULT_SIMD_1_4 (data[j], &BETA3[i]);
        *s_p \hat{ }= GF_MULT_SIMD_1_4 (data[j+1], &BETA2[i]);
        *s_p \hat{ }= GF_MULT_SIMD_1_4 (data[j+2], &BETA[i]);
        *s_p++ = XOR_SIMD_1_4 (data[j+3], &s[i]);
    }
}
// Process remaining 2 data/crc bytes
j = 253; // last iteration, j = 249. j+3 = 252
for (i = 0; i < 2*T; i++) {
    s[i] = data[j] \hat{ } GF_MULT_SCALAR (s[i], BETA[i]);
    s[i] = data[j+1] \hat{ } GF_MULT_SCALAR (s[i], BETA[i]);
}
```

This unit of processing becomes the processing kernel for the Reed Solomon decode:

```
for (j = 1; j < (N−4); j += 4) {
    for (i = 0; i < 2*T; i += 4) {
        int *s_p = (int *) &s[i];
        *s_p++ = RS_DECODE_KERNEL (&data[j], &s[i],
                      &BETA[i], &BETA2[i], &BETA3[i],
                      &BETA4[i]);
    }
}
// Process remaining 2 data/crc bytes
j = 253; // last iteration, j = 249. j+3 = 252
for (i = 0; i < 2*T; i++) {
    s[i] = data[j] \hat{ } GF_MULT_SCALAR (s[i], BETA[i]);
    s[i] = data[j+1] \hat{ } GF_MULT_SCALAR (s[i], BETA[i]);
}
```

The set of BETA constants may be obtained from a ROM index by the value of “i”. Sixteen constants are provided to each of sixteen Galios Field multipliers operating on the respective s[i] and data[j] bytes.

Both implementations of the RS_DECODE_KERNEL replaces 32 table-look-ups, 16 checks with zeros, and 16 adds for the syndrome calculation and also performs the required 16 XORS (GF adds). This is a factor of 64 in instructions issued compared to the optimized software version.

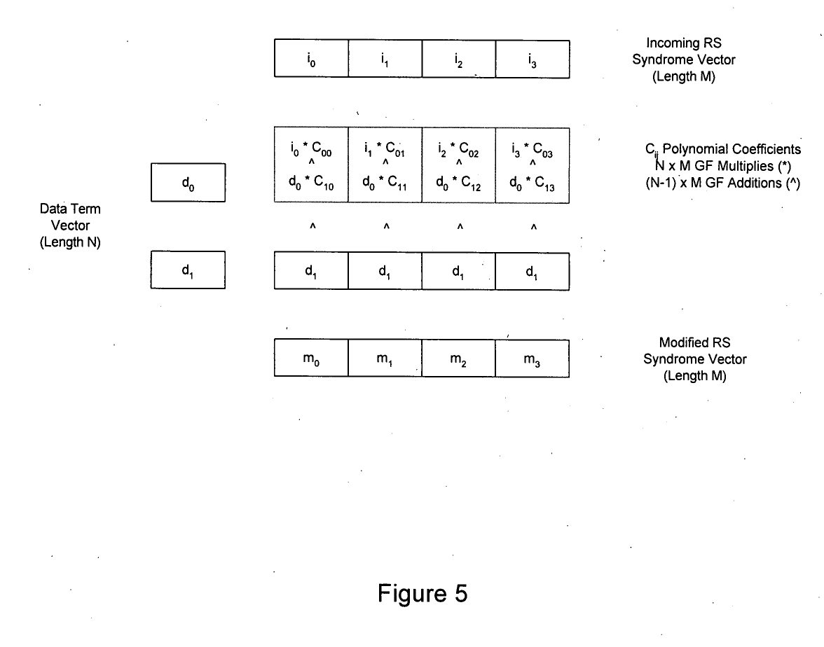

In a preferred embodiment illustrated in FIG. 5, the parallelized method used in the generation of Reed Solomon syndrome bytes utilizes multiple digital logic operations or computer instructions implemented using digital logic. At least one of the operations or instructions performs the following combinations of steps: a) provide an operand representing N data terms where N is one or greater, b) provide an operand representing M incoming Reed Solomon syndrome bytes where M is greater than one, c) computation of N by M Galios Field polynomial multiplications, d) computation of N by M Galios Field additions producing M modified Reed Solomon syndrome bytes.

In the preferred embodiment illustrated in FIG. 5, the values of N and M are two and four respectively. In the preceding code examples, the values of N and M were selected to be four as this matched the word width of the MIPS microprocessor. When N and M are both the value of four, sixteen Galios Field polynomial multiplications are computed concurrently or sequentially in a pipeline. Each Galios Field polynomial multiplication utilizes a coefficient delivered from a memory device, which in a preferred embodiment, would be implemented either by a read only memory (ROM), random access memory (RAM) or a register file. The derivation of each coefficient resulted from the application of the distributive and associative properties of Galios Field operations. The generation of Reed Solomon syndrome bytes requires several iterations each time using previous modified Reed Solomon syndrome bytes as incoming Reed Solomon syndrome bytes.

In the preferred embodiment, the method used to simplify coefficients used in this parallelized Reed Solomon decoder required a) expanding formulas for syndrome byte operations, b) applying distributive and associative properties of Galios Field operations, c) grouping multiple constants together using the same multiple type Galios Field operation, and d) forming a single aggregate constant in place of multiple constants and multiple operations. Creation of the constants BETA2, BETA3 and BETA4 representing precomputed powers of BETA is the result of the restructured computations and simplified constants used in this preferred embodiment of the parallelized Reed Solomon decoder.

### 6.1.5 RS Decode Kernel Further Improved

The Reed Solomon Decode Kernel may be further improved by the use of improvements suggested for Reed Solomon Encode Kernel. The improvements however are limited as special beginning and ending is not used within the outer loop but outside of the outer loop. Specifically, the BETA coefficients used are shifted and BETA0[x] is defined to be BETA to the zero-th power, i.e. the value of 1. Further, the data array is extended with zero values. The implementation hence becomes:

```
// Process remaining 2 data/crc bytes
byte d[4];
d[0] = data[253];
d[1] = data[254];
d[2] = 0;
d[3] = 0;
for (i = 0; i < 2*T; i += 4) {
      int *s_p = (int *) &s[i];
      *s_p++ = RS_DECODE_KERNEL (&d[0], &s[i], &BETA0[i],
                            &BETA0[i], &BETA1[i], &BETA2[i]);
}
```

6.2 Finding the Error Location Polynomial using the Berlekamp-Massey Algorithm

If the syndromes calculated in parity check are not zero, then there are error(s) in the received codeword. We must solve the linear set of equations in order to obtain the error-locator polynomial σ(x) defined as:

$$[ \begin{matrix}{s}_{1} & {s}_{2} & … & {s}_{t} \\ {s}_{2} & {s}_{3} & … & {s}_{t + 1} \\ … & … & … & … \\ {s}_{t} & {s}_{t + 1} & … & {s}_{2 t}\end{matrix} ] [ \begin{matrix}{σ}_{t} \\ {σ}_{t - 1} \\ … \\ {σ}_{1}\end{matrix} ] = [ \begin{matrix}{s}_{t + 1} \\ {s}_{t + 2} \\ … \\ {s}_{2 t}\end{matrix} ]$$

General methods can be used to solve the above system, but an iterative method has been developed as will be described below. The syndromes are equivalent to the following:

s=rH^{T}=(ν+e)H^{T}=eH^{T}

hence sᵢ=e(α¹)=e₀+e₁αⁱ+ . . . +e_{N-1}α^{(N-1)i}

Now the error pattern e(X)=X^{j}^{₁}+X^{j}^{₂}+ . . . +X^{j}^{_{ν}} has v-errors at locations j₁, j₂, . . . , j_{ν} which can be solve by the set of equations:

$${s}_{1} = {α}^{j 1} + {α}^{j 2} + … + {α}^{jv}$$

$${s}_{2} = {( {α}^{j 1} )}^{2} + {( {α}^{j 2} )}^{2} + … + {( {α}^{j v} )}^{2}$$

$${s}_{3} = {( {α}^{j 1} )}^{3} + {( {α}^{j 2} )}^{3} + … + {( {α}^{j v} )}^{3}$$

$$…$$

$$…$$

$$…$$

$${s}_{2 T} = {( {α}^{j 1} )}^{2 T} + {( {α}^{j 2} )}^{2 T} + … + {( {α}^{j v} )}^{2 T}$$

where α^{ji} are unknown. Once α^{ji} are found, the powers j₁, j₂, . . . , j_{ν} tell us the error locations in e(x). There are many solutions to the above equations where the solution that yields an error pattern with the smallest number of errors is the right solution. For convenience, let

Bᵢα^{ji} now the above equations can be rewritten as:

s₁=B₁+B₂+ . . . +B_{ν}

s₂=B₁²+B₂²+ . . . +B_{ν}²

s₃=B₁³+B₂³+ . . . +B_{ν}³

s_{2T}=B₁^{2T}+B₂^{2T}+ . . . +B_{ν}^{2T}

The 2T equations are symmetric functions in B₁, B₂, . . . , B_{ν} which are know as power-sum symmetric functions. Now we define the “error-locator” polynomial

ν(x)=(1+B₁X)(1+B₂X) . . . (1+B_{ν}X)=σ₀+ν₁X+σ₂X²+ . . . +σ_{ν}X^{ν}

The roots of ν(x) are the inverses of B₁, B₂, . . . , B_{ν} and also the inverse of the error location numbers. The coefficients of σ(x) and the error-location numbers are related by the following equations (a way of finding coefficients for a polynomial):

$${σ}_{0} = 1$$

$${σ}_{1} = {B}_{1} + {B}_{2} + … + {B}_{v}$$

$${σ}_{2} = {B}_{1} {B}_{2} + {B}_{2} {B}_{3} + … + {B}_{v - 1} {B}_{v}$$

$$…$$

$$…$$

$$…$$

$${σ}_{v} = {B}_{1} {B}_{2 } … {B}_{v}$$

Combining the above equations we see that the syndromes and coefficients of the error locator polynomial are by the following Newton's identities.

s₁+σ₁=0

s₂+σ₁s₁+2σ₂=0

s₃+σ₁s₂+σ₂s₁+3σ₃=0

s_{ν}+σ₁s_{ν-1}+ . . . +σ_{ν-1}s₁+νσ_{ν}=0

s_{ν+1}+σ₁s_{ν}+ . . . +σ_{ν-1}s₂+σ_{ν}s₁=0

with the above set of equations we obtain the error-location polynomial

σ(X)=σ₀+σ₁X+σ₂X²+ . . . +σ_{ν}X^{ν}.

As one can see from the above set of equations, a structure is present and an iterative algorithm for finding the error-locator polynomial is the Berlekamp's iterative algorithm.

| | |
|---|---|
| σ(x) = 1 | // lambda, error locator polynomial |

| | |
|---|---|
| L = 0; | //degree of lambda, number of errors = v |

| | |
|---|---|
| T(x) = x; | //correction polynomial |

| | |
|---|---|
| for (k = 1; k <= 2*T; k++) { | // must iterate for all syndromes and all Newton identities |

| | |
|---|---|
| $error = {s}_{k} - {\sum }_{i = 1}^{L} {σ}_{i}^{k - 1} {s}_{k - 1} ;$ | //calculate the error |

| | |
|---|---|
| σ(x)_old = σ(x); | //need a copy before we modify |

| | |
|---|---|
| σ(x) = σ(x) − error *T(x); | //error can equal zero |

if ((2*L < k) && (error != 0)) {

| L = k − L; | |
|---|---|
| $T ( x ) = \frac{σ ( x ) \_old}{error} ;$ | //new correction polynomial |

| } | |
|---|---|
| T(x) = x*T(x); | // shift the correction polynomial (multiplying by X is just a shift) |

}

The order of magnitude for the Berlekamp-Massey algorithm is 0(2T̂2). Please note, even with special purpose hardware for the GF multiplication, a table look-up is needed for the inverse of the error value. Implementation of the Berlekamp-Massey algorithm will take advantage of a GF instruction but the order of magnitude is much smaller than the parity check (syndrome calculation) and Chien search so operations counts have been omitted.

### 6.3 Finding the Roots of the Error-Locator Polynomial: Chien Search Algorithm

After finding the error-location polynomial σ(x), we must find the reciprocals of the roots of σ(x) which gives one the error-location numbers. The roots of σ(x) can be found by substituting the primitive elements 1, α, α², . . . , α^{N-1} (n=2⁸−1) into σ(x). Since α^{N}=1,α⁻ⁱ=α^{N-i}, therefore if α^{j} is a root of σ(x) then α^{N-j} is an error-location number and the received byte r_{N-j} has an error.

The Chien procedure (fancy name for a brute force search) for searching error-location numbers is as follows:

r(x)=r₀+r₁X+r₂X²+ . . . +r_{N-1}X^{N-1}.

To decode r_{N-i} the decoder tests whether β^{N-i} is an error-location number. This is equivalent to testing whether its inverse, αⁱ is a root of σ(x). If αⁱ is a root of 1+σ₁αⁱ+σ₂α²ⁱ+ . . . ασ_{ν}α^{νi} then r_{N-i} has an error.

1+σ₁αⁱ+σ₂α²ⁱ+ . . . +σ_{ν}α^{νi} can be rewritten as:

$$result ( \text{:} N ) = [ {I}_{N} ⊗ 1 ] + [ \begin{matrix}{σ}_{1} & {σ}_{2} & … & {σ}_{v}\end{matrix} ] [ \begin{matrix}{α}^{i} & {α}^{( i + 1 )} & … & {α}^{( N )} \\ {α}^{2 i} & {α}^{2 ( i + 1 )} & … & {α}^{2 ( N )} \\ … & … & … & … \\ {α}^{vi} & {α}^{v ( i + 1 )} & … & {α}^{v ( N )}\end{matrix} ]$$

Note that σα⁽ⁱ⁺¹⁾=σαⁱα so the column (i+1) is constructed by column (i) recursively as follows:

$$[ {σ}_{1 } {σ}_{2} … {σ}_{v} ] [ \begin{matrix}{α}^{( i + 1 )} \\ {α}^{2 ( i + 1 )} \\ … \\ {α}^{v ( i + 1 )}\end{matrix} ] = [ \begin{matrix}{σ}_{1} & {σ}_{2} & … & {σ}_{v}\end{matrix} ] [ \begin{matrix}α & & & \\ & {α}^{2} & & \\ & & … & \\ & & & {α}^{v}\end{matrix} ] [ \begin{matrix}{α}^{i} \\ {α}^{2 i} \\ … \\ {α}^{vi}\end{matrix} ]$$

The c-code is shown in the next section.

### 6.4.1 Optimized Software

| | |
|---|---|
| for (i = 0; i <= N; i++) { | |
| q = 1; /* lambda[0] is always 0 */ | |
| for (j = deg_lambda; j > 0; j−−) { | |
| if (lambda[j] != 0) { | |
| lambda[j] = MODNN (lambda[j] + j); | // log form might |
| | // not need the |
| | MODNN for |
| | some codes |
| q \hat{ }= ANTI_LOG[lambda[j]]; | |
| } | |
| } | |
| } | |

### 6.4.2 Scalar GF Hardware

The above code can be rewritten with the GF_MULT_SCALAR instruction as follows:

```
for (i = 0; i <= N; i++) {
    q = 1;
    for (j = deg_lambda; j > 0; j−−) {
        lambda[j] = GF_MULT_SCALAR (lambda[j], alpha[j]);
        q \hat{ }= lambda[j];
    }
}
```

The GF_MULT_SCALAR replaces one table look-up, a check with zero, and one add.

### 6.4.3 SIMD GF Multiply

Using the GF_SIMD_MULT instruction, the code is as follows:

```
for (i = 0; i <= N; i++) {
  q = 1;
  for (j = deg_lambda; j > 0; j −= 4) {
    lambda[j%4] = GF_MULT_SIMD (lambda[j%4], alpha[j%4]);
    q \hat{ }= lambda[j+3] \hat{ } lambda[j+2] \hat{ } lambda[j+1] \hat{ } lambda[j];
  }
}
```

The GF_MULT_SIMD instruction replaces 4 table look-ups, 4 checks with zero, and 4 adds.

For a RS(N,K) syndrome calculation, (T/4)*N GF_MULT_SIMD instructions replaces:

1) T*N table look-up (max degree lambda=T)

2) T*N checks with zero

3) T*N adds

Example:

The RS(255,223) code without a Gf instruction requires:

1) 16*255=4080 table look-ups

2) 16*255=4080 checks with zeros

3) 16*255=4080 adds (totaling ˜12240 instructions to issue)

The RS(255,223) code with a GF_MULT_SIMD instruction requires:

1) N*(T/4)=255*16/4=1020 GF_MULT_SIMD instructions
Again, the GF_MULT_SIMD instruction greatly reduces the number of instructions issued from 12,240 to 1020 which is a factor of 12.

### 6.5 Compute the Error Magnitudes Using Forney's Algorithm

The Forney algorithm is used to calculate the set of t-linear equations that have to be solved in order to find the error magnitudes. The algorithm is as follows:

The error-evaluator polynomial Ω(x) is defined by:

Ω(x)=S(x)σ(x)mod x²T

where S(x) is the syndrome polynomial and σ(x) is the error-locator polynomial.

The coefficient of x^{ν+j-1} in S(x)σ(x) is 0 if 1≦j≦2T−ν therefore

deg(S(x)σ(x)mod x²T)<ν.

The error-evaluator polynomial can be computed explicitly from σ(x) as follows:

Ω₀=S₁

Ω₁=S₂+S₁σ₁

Ω₂=S₃+S₂σ₁+S₁σ₂

. . .

Ω_{ν-1}=S_{ν}+S_{ν-1}ν₁+ . . . +S₁σ_{ν-1}

Now suppose a RS code defined by zeroes α¹, α², . . . , α^{2T-1}

The error magnitude Yᵢ corresponding to error location number Xᵢ is:

$${Y}_{i} = \frac{Ω ( {X}_{i}^{- 1} )}{{σ}^{′} ( {X}_{i}^{- 1} )}$$

where σ(x) is formal derivative of error-locator polynomial:

$${σ}^{′} ( X ) = {\sum }_{i = 1}^{v} i {σ}_{i} {X}^{i - 1} = {σ}_{1} + 2 {σ}_{2} X + 3 {σ}_{3} {X}^{2} + … + v {σ}_{v} {X}^{v - 1}$$

In fields with characteristic elements 2, the formal derivative has no coefficients corresponding to odd powers of the indeterminant (i.e. X^{j}=0 if j is odd) since 2=1+1=0, 4=2+2=2(1+1)=0, and so on. Hence the derivative of the error-locator polynomial is simply,

σ(X)=σ₁+3σ₃X²+5σ₅X⁴+ . . .

The order of magnitude for the Forney algorithm is 0(T̂2). Implementation of the Forney algorithm will take advantage of a GF instruction but the order of magnitude is much smaller than the parity check (syndrome calculation) and Chien search so operations counts have been omitted.

### 6.6 Reed Solomon Decode Performance on the MIPS Processor

Using the popular RS(255,223) coder as an example, the following table summarizes the MIPS required per megabit of user data and the approximate gate count for each of the recommended implementations:

| | Decode | Decode | | |
|---|---|---|---|---|
| | Syndrome | Correction | Gates | ROM |
| Optimized MIPS Assembly | 37.0 | 47.6 | none | none |
| Scalar GF Multiply Support | 5.1 | 27.8 | 600 | none |
| SIMD GF Multiply Support | 1.7 | 10.2 | 1560 | 4 × 32 bytes |
| RS Decode Kernel Support | 0.44 | 10.2 | 6240 | 1024 bytes |

Note: Additional optimization by use of register variables was not shown but is assumed to provide the performance numbers given above. Also, the optimization shown in a prior section extending either the data and/or coefficient array is also possible with other suggested implementations. These improvements would be obvious to one skilled in the art along with this teaching and is not explicitly shown in this specification. The MIPS projections given in the tables below assume all of these optimizations are exploited.

### 7. Instructions

### 7.1 RS Encode Instructions

### 7.1.1 Reed Solomon Encode Scalar Multiply and Accumulate

| | |
|---|---|
| Mnemonic: | rs_enc_scalar_alpha_xx $dst, $src1, $src2 |
| Operation: | $dst[07:00] = $src1[07:00] \hat{ } gf_mult ($src2[07:00], |
| | alpha[xx]) |
| | $dst[31:08] = 0 |
| Where: | $dst bits 7:0 are the result of the operation |
| | $dst bits 31:8 are zero |
| | $src1 bits 7:0 are the previous crc bits to be exclusive or-ed |
| | $src1 bits 31:8 are ignored |
| | $src2 bits 7:0 are the feedback byte for the gf_mult |
| | operation |
| Cycles: | One clock cyle execution. |
| Instruction | Three operand UDI instruction to encode $dst, |
| Encoding: | $src1 and $src2. |
| | Bits 4 to 0 address the specific alpha coefficient |
| | (one of 32) to be used. |
| | rs_enc_scalar_alpha_0 |
| | rs_enc_scalar_alpha_1 |
| | . . . |
| | rs_enc_scalara_alpha_31 |

Notes:
1. The $dst bits 31:8 are set to zero, to avoid the “and” operation at the end of the register optimized loop when creating the byte crc operands for crc bytes 0, 1, 2 and 3. When creating fb from fb0, fb1, fb2 and fb3, it is assumed that the high order bits of each individual term are zero.

### 7.1.2 Reed Solomon Encode SIMD Multiply and Accumulate

| | |
|---|---|
| Mnemonic: | rs_enc_simd_alpha_xx $dst, $src1, $src2 |
| Operation: | $dst[31:00] = $src1[31:00] \hat{ } ((gf_mult ($src2[07:00], |
| | alpha[xx+0]) << 0) \| |
| | (gf_mult ($src2[07:00], alpha[xx+1]) << 8) \| |
| | (gf_mult ($src2[07:00], alpha[xx+2]) << 16)\| |
| | (gf_mult ($src2[07:00], alpha[xx+3]) << 24)) |
| Where: | $dst bits 31:0 are the result of the operation |
| | $src1 bits 31:0 are the previous crc bits to be exclusive |
| | or-ed |
| | $src2 bits 7:0 are the feedback byte for the gf_mult |
| | operation |
| Cycles: | One clock cyle execution. |
| Instruction | Three operand UDI instruction to encode $dst, |
| Encoding: | $src1 and $src2. Bits 4 to 0 address |
| | the specific set of alpha coefficients (one of 29) to be used. |
| | rs_enc_simd_alpha_0 |
| | rs_enc_simd_alpha_1 |
| | rs_enc_simd_alpha_27 |
| | rs_enc_simd_alpha_28 (see note 2) |

Notes:
1. The instruction automatically uses a set of coefficients beginning with alpha[xx].
2. Only rs_enc_simd_alpha_28 is used with the rs_enc_kernel_alpha_xx instructions. If SIMD instructions are not supported when using the KERNEL instructions, four individual SCALAR instructions would be used instead.

### 7.1.3 Reed Solomon Encode Kernel Multiply and Accumulate

| Mnemonic: | rs_enc_kernel_alpha_xx $dst, $src1, $src2 | | |
|---|---|---|---|
| Operation: | $dst[31:00] = $src1[31:00] | \hat{ } ((gf_mult ($src2[31:24], alpha[xx+0]) << 0) | \| |
| | | (gf_mult ($src2[31:24], alpha[xx+1]) << 8) | \| |
| | | (gf_mult ($src2[31:24], alpha[xx+2]) << 16) | \| |
| | | (gf_mult ($src2[31:24], alpha[xx+3]) << 24)) | |
| | | \hat{ } ((gf_mult ($src2[23:16], alpha[xx+1]) << 0) | \| |
| | | (gf_mult ($src2[23:16], alpha[xx+2]) << 8) | \| |
| | | (gf_mult ($src2[23:16], alpha[xx+3]) << 16) | \| |
| | | (gf_mult ($src2[23:16], alpha[xx+4]) << 24)) | |
| | | \hat{ } ((gf_mult ($src2[15:08], alpha[xx+2]) << 0) | \| |
| | | (gf_mult ($src2[15:08], alpha[xx+3]) << 8) | \| |
| | | (gf_mult ($src2[15:08], alpha[xx+4]) << 16) | \| |
| | | (gf_mult ($src2[15:08], alpha[xx+5]) << 24)) | |
| | | \hat{ } ((gf_mult ($src2[07:00], alpha[xx+3]) << 0) | \| |
| | | (gf_mult ($src2[07:00], alpha[xx+4]) << 8) | \| |
| | | (gf_mult ($src2[07:00], alpha[xx+5]) << 16) | \| |
| | | (gf_mult ($src2[07:00], alpha[xx+6]) << 24)) | |

| | |
|---|---|
| Where: | $dst bits 31:0 are the result of the operation |
| | $src1 bits 31:0 are the previous crc bits to be exclusive or-ed |
| | $src2 bits 7:0, 15:8, 23:16 and 31:24 are the first, second, third and fourth |
| | feedback bytes (in time sequence or data order) for the gf_mult operation |
| Cycles: | One clock cyle execution. |
| Instruction Encoding: | Three operand UDI instruction to encode $dst, $src1 and $src2. Bits 2 to 0 address |
| | the specific set of alpha coefficients (one of 7) to be used. |
| | rs_enc_kernel_alpha_0 |
| | rs_enc_kernel_alpha_4 |
| | rs_enc_kernel_alpha_8 |
| | rs_enc_kernel_alpha_12 |
| | rs_enc_kernel_alpha_16 |
| | rs_enc_kernel_alpha_20 |
| | rs_enc_kernel_alpha_24 |
| | rs_enc_simd_alpha_28 (see note 2) |

Notes:
1. The instruction automatically uses a set of coefficients beginning with alpha[xx].
2. Only rs_enc_simd_alpha_28 is used with the rs_enc_kernel_alpha_xx instructions. The eight alpha_xx instruction coding may be used for this single SIMD instruction.

### 7.1.4 Alpha Coefficient Memory

For optimum implementation, the polynomial constants are read from a ROM (or RAM). Seven Alpha coefficients are need for the ENCODE_KERNEL operation. Duplicate copies of coefficients may be stored in the ROM so as to deliver sixteen independent coefficients to the sixteen Galios Field multiplers.

Run-time hardware may be eliminated by precomputing the set of polynomial terms used by the GF multiplier. These may also be read from a ROM (or RAM).

Remember, the coefficients used for an optimal software implementation are in the LOG domain. The coefficients used for hardware implementation are not transformed.

### 7.2 RS Decode Instructions

### 7.2.1 Reed Solomon Decode Scalar Multiply and Accumulate

| | |
|---|---|
| Mnemonic: | rs_dec_scalar_beta_xx $dst, $src1, $src2 |
| Operation: | $dst[07:00] = $src1[07:00] \hat{ } gf_mult ($src2[07:00], |
| | beta[xx]) |
| | $dst[31:00] = 0 |
| Where: | $dst bits 7:0 are the result of the operation |
| | $dst bits 31:8 are zero |
| | $src1 bits 7:0 are the new data bits to be exclusive or-ed |
| | $src1 bits 31:8 are ignored |
| | $src2 bits 7:0 are the previous syndrome byte for the |
| | gf_mult operation |
| Cycles: | One clock cyle execution. |
| Instruction | Three operand UDI instruction to encode $dst, $src1 |
| Encoding: | and $src2. Bits 4 to 0 address |
| | the specific beta coefficient (one of 32) to be used. |
| | rs_dec_scalar_beta_0 |
| | rs_dec_scalar_beta_1 |
| | . . . |
| | rs_dec_scalar_beta_31 |

Notes:
(none)

7.2.2 Reed Solomon Decode Scalar Multiply and Accumulate with Byte Location

| | |
|---|---|
| Mnemonic: | rs_dec_scalar_z_beta_xx $dst, $src1, $src2 |
| Operation: | (for z = 0) |
| | $dst[07:00] = $src1[07:00] \hat{ } gf_mult ($src2[07:00], beta[xx]) |
| | $dst[31:08] = 0 |
| | (for z = 1) |
| | $dst[15:08] = $src1[07:00] \hat{ } gf_mult ($src2[15:08], beta[xx]) |
| | $dst[07:00] = 0 |
| | $dst[31:00] = 0 |
| | (for z = 0) |
| | $dst[23:16] = $src1[07:00] \hat{ } gf_mult ($src2[23:16], beta[xx]) |
| | $dst[15:00] = 0 |
| | $dst[31:24] = 0 |
| | (for z = 3) |
| | $dst[31:24] = $src1[07:00] \hat{ } gf_mult ($src2[31:24], beta[xx]) |
| | $dst[23:00] = 0 |
| Where: | (for z = 0) |
| | $dst bits 7:0 are the result of the operation |
| | $dst bits 31:8 are preserved |
| | $src1 bits 7:0 are the new data bits to be exclusive or-ed |
| | $src1 bits 31:8 are ignored |
| | $src2 bits 7:0 are the previous syndrome byte for the gf_mult operation |
| | (for z = 1) |
| | $dst bits 15:8 are the result of the operation |
| | $dst bits 7:0 are preserved |
| | $dst bits 31:16 are preserved |
| | $src1 bits 7:0 are the new data bits to be exclusive or-ed |
| | $src1 bits 31:8 are ignored |
| | $src2 bits 15:8 are the previous syndrome byte for the gf_mult operation |
| | (for z = 2) |
| | $dst bits 23:16 are the result of the operation |
| | $dst bits 15:0 are preserved |
| | $dst bits 31:24 are preserved |
| | $src1 bits 7:0 are the new data bits to be exclusive or-ed |
| | $src1 bits 31:8 are ignored |
| | $src2 bits 23:16 are the previous syndrome byte for the gf_mult operation |
| | (for z = 3) |
| | $dst bits 31:24 are the result of the operation |
| | $dst bits 23:0 are preserved |
| | $src1 bits 7:0 are the new data bits to be exclusive or-ed |
| | $src1 bits 31:8 are ignored |
| | $src2 bits 31:24 are the previous syndrome byte for the gf_mult operation |
| Cycles: | One clock cyle execution. |
| Instruction Encoding: | Three operand UDI instruction to encode $dst, $src1 and $src2. Bits 4 to 0 address |
| | the specific beta coefficient (one of 32) to be used. |
| | rs_dec_scalar_0_beta_0 |
| | rs_dec_scalar_1_beta_1 |
| | . . . |
| | rs_dec_scalar_3_beta_31 |

Notes:
1. This instruction form would be used for optimized packed bytes held in the processor registers.

### 7.2.3 Reed Solomon Decode SIMD Multiply and Accumulate

| Mnemonic: | rs_dec_simd_beta_xx $dst, $src1, $src2 | |
|---|---|---|
| Operation: | $dst[31:00] = (($src1[07:00] << 0) | \| |

| | |
|---|---|
| ($src1[07:00] << 8) | \| |
| ($src1[07:00] << 16) | \| |
| ($src1[07:00] << 23)) | |

| | |
|---|---|
| \hat{ } ((gf_mult ($src2[07:00], beta[xx+0]) << 0) | \| |
| (gf_mult ($src2[15:08], beta[xx+1]) << 8) | \| |
| (gf_mult ($src2[23:16], beta[xx+2]) << 16) | \| |
| (gf_mult ($src2[31:24], beta[xx+3]) << 23)) | |

| | |
|---|---|
| Where: | $dst bits 31:0 are the result of the operation |
| | $src1 bits 7:0 are the new data bits to be exclusive or-ed |
| | $src1 bits 31:8 are ignored |
| | $src2 bits 31:0 are the four previous syndrome bytes for the |
| | gf_mult operation |
| Cycles: | One clock cyle execution. |
| Instruction | Three operand UDI instruction to encode $dst, |
| Encoding: | $src1 and $src2. Bits 2 to 0 address |
| | the specific set of alpha coefficients (one of 8) to be used. |
| | rs_dec_simd_beta_0 |
| | rs_dec_simd_beta_4 |
| | rs_dec_simd_beta_8 |
| | rs_dec_simd_beta_12 |
| | rs_dec_simd_beta_16 |
| | rs_dec_simd_beta_20 |
| | rs_dec_simd_beta_24 |
| | rs_dec_simd_beta_28 |

Notes:
1. The instruction automatically uses a set of coefficients beginning with beta[xx].

### 7.2.4 Reed Solomon Decode Kernel Multiply and Accumulate

| Mnemonic: | rs_dec_kernel_beta_xx $dst, $src1, $src2 | |
|---|---|---|
| Operation: | $tmp[07:00] = $src1[31:24] /* Spread data[3] to all four positions */ | |
| | $tmp[15:08] = $src1[31:24] | |
| | $tmp[23:16] = $src2[31:24] | |
| | $tmp[31:24] = $src1[31:24] | |
| | $dst[31:00] = (($src1[31:24] << 0) \| | |
| | ($src1[31:24] << 8) | \| |
| | ($src1[31:24] << 16) | \| |
| | ($src1[31:24] << 23)) | |

| | |
|---|---|
| \hat{ } ((gf_mult ($src1[23:16], beta[xx+0]) << 0) | \| |
| (gf_mult ($src1[23:16], beta[xx+1]) << 8) | \| |
| (gf_mult ($src1[23:16], beta[xx+2]) << 16) | \| |
| (gf_mult ($src1[23:16], beta[xx+3]) << 24)) | |
| \hat{ } ((gf_mult ($src1[15:08], beta2[xx+0]) << 0) | \| |
| (gf_mult ($src1[15:08], beta2[xx+1]) << 8) | \| |
| (gf_mult ($src1[15:08], beta2[xx+2]) << 16) | \| |
| (gf_mult ($src1[15:08], beta2[xx+3]) << 24)) | |
| \hat{ } ((gf_mult ($src1[07:00], beta3[xx+0]) << 0) | \| |
| (gf_mult ($src1[07:00], beta3[xx+1]) << 8) | \| |
| (gf_mult ($src1[07:00], beta3[xx+2]) << 16) | \| |
| (gf_mult ($src1[07:00], beta3[xx+3]) << 24)) | |
| \hat{ } ((gf_mult ($src2[07:00], beta4[xx+0]) << 0) | \| |
| (gf_mult ($src2[15:08], beta4[xx+1]) << 8) | \| |
| (gf_mult ($src2[23:16], beta4[xx+2]) << 16) | \| |
| (gf_mult ($src2[31:24], beta4[xx+3]) << 24)) | |

| | |
|---|---|
| Where: | $dst bits 31:0 are the result of the operation |
| | $src1 bits 31:0 are the four new data bytes for the gf_mult operation |
| | $src2 bits 31:0 are the four previous syndrome bytes for the gf_mult operation |
| Cycles: | One clock cyle execution. |
| Instruction Encoding: | Three operand UDI instruction to encode $dst, $src1 and $src2. Bits 2 to 0 address |
| | the specific set of alpha coefficients (one of 8) to be used. |
| | rs_dec_kernel_beta_0 |
| | rs_dec_kernel_beta_4 |
| | rs_dec_kernel_beta_8 |
| | rs_dec_kernel_beta_12 |
| | rs_dec_kernel_beta_16 |
| | rs_dec_kernel_beta_20 |
| | rs_dec_kernel_beta_24 |
| | rs_dec_kernel_beta_28 |

Notes:
1. The instruction automatically uses a set of coefficients beginning with beta[xx], beta2[xx], beta3[xx] and beta4[xx]. The coefficients beta2, beta3 and beta4 are beta to power of two, three and four respectively.

### 7.2.5 Reed Solomon Decode Kernel Multiply and Accumulate End

| Mnemonic: | rs_dec_kernel_beta_xx_end $dst, $src1, $src2 | |
|---|---|---|
| Operation: | $tmp[07:00] = $src1[31:24] /* Spread data[3] to all four positions */ | |
| | $tmp[15:08] = $src1[31:24] | |
| | $tmp[23:16] = $src1[31:24] | |
| | $tmp[31:24] = $src1[31:24] | |
| | $dst[31:00] = (($src1[31:24] << 0) \| | |
| | ($src1[31:24] << 8) | \| |
| | ($src1[31:24] << 16) | \| |
| | ($src1[31:24] << 23)) | |

| | |
|---|---|
| \hat{ } ((gf_mult ($src1[23:16], beta0[xx+0]) << 0) | \| |
| (gf_mult ($src1[23:16], beta0[xx+1]) << 8) | \| |
| (gf_mult ($src1[23:16], beta0[xx+2]) << 16) | \| |
| (gf_mult ($src1[23:16], beta0[xx+3]) << 24)) | |
| \hat{ } ((gf_mult ($src1[15:08], beta[xx+0]) << 0) | \| |
| (gf_mult ($src1[15:08], beta[xx+1]) << 8) | \| |
| (gf_mult ($src1[15:08], beta[xx+2]) << 16) | \| |
| (gf_mult ($src1[15:08], beta[xx+3]) << 24)) | |
| \hat{ } ((gf_mult ($src1[07:00], beta2[xx+0]) << 0) | \| |
| (gf_mult ($src1[07:00], beta2[xx+1]) << 8) | \| |
| (gf_mult ($src1[07:00], beta2[xx+2]) << 16) | \| |
| (gf_mult ($src1[07:00], beta2[xx+3]) << 24)) | |
| \hat{ } ((gf_mult ($src2[07:00], beta3[xx+0]) << 0) | \| |
| (gf_mult ($src2[15:08], beta3[xx+1]) << 8) | \| |
| (gf_mult ($src2[23:16], beta3[xx+2]) << 16) | \| |
| (gf_mult ($src2[31:24], beta3[xx+3]) << 24)) | |

| | |
|---|---|
| Where: | $dst bits 31:0 are the result of the operation |
| | $src1 bits 31:0 are the four new data bytes for the gf_mult operation |
| | $src2 bits 31:0 are the four previous syndrome bytes for the gf_mult operation |
| Cycles: | One clock cyle execution. |
| Instruction Encoding: | Three operand UDI instruction to encode $dst, $src1 and $src2. Bits 2 to 0 address |
| | the specific set of alpha coefficients (one of 8) to be used. |
| | rs_dec_kernel_beta_0_end |
| | rs_dec_kernel_beta_4_end |
| | rs_dec_kernel_beta_8_end |
| | rs_dec_kernel_beta_12_end |
| | rs_dec_kernel_beta_16_end |
| | rs_dec_kernel_beta_20_end |
| | rs_dec_kernel_beta_24_end |
| | rs_dec_kernel_beta_28_end |

Notes:
1. The instruction automatically uses a set of coefficients beginning with beta0[xx], beta[xx], beta2[xx] and beta3[xx]. All values of beta0[xx] are unity, i.e. one.
2. This instruction is used as per the example code for processing the data remaining after the processing loop has completed. In a general implementation, three different ending instructions may be required where the first is used with 3 data bytes (as shown here), the next us used with two data bytes and the last is used with one data bytes. These later two forms would simple repeat beta0[xx] two and three times respectively and use fewer beta power terms.

### 7.2.6 Beta Coefficient Memory

For optimum implementation, the polynomial constants are read from a ROM (or RAM). Sixteen Beta coefficients are need for the DECODE_KERNEL operation delivered to each of the Galios Field multipliers.

Run-time hardware may be eliminated by precomputing the set of polynomial terms used by the GF multiplier. These may also be read from a ROM (or RAM).

Remember, the coefficients used for an optimal software implementation are in the LOG domain. The coefficients used for hardware implementation are not transformed.

### 7.3 Galois Field Instructions

### 7.3.1 GF Scalar Multiply

| | |
|---|---|
| Mnemonic: | gf_mult_scalar $dst, $src1, $src2 |
| Operation: | $dst[07:00] = gf_mult ($src1[07:00], $src2[07:00]) |
| | $dst[31:08] = 0 |
| Where: | $dst bits 7:0 are the result of the operation |
| | $dst bits 31:8 are zero |
| | $src1 bits 7:0 are the first multiply operand |
| | $src1 bits 31:8 are ignored |
| | $src2 bits 7:0 are the second multiply operand |
| | $src2 bits 31:8 are ignored |
| Cycles: | One clock cyle execution. |
| Instruction | Three operand UDI instruction to encode |
| Encoding: | $dst, $src1 and $src2. |

Notes:
1. The $dst bits 31:8 are set to zero, to avoid the “and” operation at the end of the register optimized loop when creating the byte operands for bytes 0, 1, 2 and 3.

### 7.3.2 GF_SIMD Scalar/Vector Multiply

| Mnemonic: | gf_simd_1_4 $dst, $src1, $src2 | |
|---|---|---|
| Operation: | $dst[31:00] = ((gf_mult ($src1[07:00], $src2[07:00]) << 0) \| | |
| | (gf_mult ($src1[07:00], $src2[15:08]) << 8) | \| |
| | (gf_mult ($src1[07:00], $src2[23:16]) << 16) | \| |
| | (gf_mult ($src1[07:00], $src2[31:24]) << 24)) | |

| | |
|---|---|
| Where: | $dst bits 31:0 are the result of the operation |
| | $src1 bits 7:0 is the first multiply operand (scalar) |
| | $src2 bits 31:0 are the second four byte packed multiply operands |
| Cycles: | One clock cyle execution. |
| Instruction Encoding: | Three operand UDI instruction to encode $dst, $src1 and $src2. |

Notes:
1. This performs a multiplication of a scalar ($src1) times all four elements of a vector ($src2) producing a four element vector of results ($dst).

### 7.3.3 GF_SIMD Vector/Vector Multiply

| Mnemonic: | gf_simd_4_4 $dst, $src1, $src2 | |
|---|---|---|
| Operation: | $dst[31:00] = ((gf_mult ($src1[07:00], $src2[07:00]) << 0) \| | |
| | (gf_mult ($src1[15:08], $src2[15:08]) << 8) | \| |
| | (gf_mult ($src1[23:16], $src2[23:16]) << 16) | \| |
| | (gf_mult ($src1[31:24], $src2[31:24]) << 24)) | |

| | |
|---|---|
| Where: | $dst bits 31:0 are the result of the operation |
| | $src1 bits 31:0 are the first four byte packed multiply operands |
| | $src2 bits 31:0 are the second four byte packed multiply operands |
| Cycles: | One clock cyle execution. |
| Instruction Encoding: | Three operand UDI instruction to encode $dst, $src1 and $src2. |

Notes:
1. This performs a multiplication of a four element vector ($src1) times a four elements of a vector ($src2) to produce a four element vector of results ($dst).

### 8. Program File Description

The implementation of the optimized source code is incorporated by reference herein is a computer program listing appendix submitted on compact disk (CDROM) herewith and containing ASCII copies of the following files: ccsds_tab.c 2,626 byte created Nov. 18, 2002; compile_patent.h 5,398 byte created Nov. 20, 2002; decode_rs.c 7,078 byte created Nov. 25, 2002; decode_rs_opt_hw.c 27,624 byte created Dec. 20, 2002; decode_rs_opt_sw.c 12,543 byte created Dec. 20, 2002; decode_rs_patent.c 120,501 byte created Dec. 20, 2002; encode_rs.c 4,136 byte created Nov. 20, 2002; encode_rs_opt_hw.c 20,920 byte created Dec. 20, 2002; encode_rs_opt_sw.c 11,549 byte created Dec. 20, 2002; encode_rs_patent.c 115,417 byte created Dec. 20, 2002; fixed.h 973 byte created Jan. 1, 2002; fixed_opt.h 2,042 byte created Nov. 25, 2002; gf_mult.c 11,841 byte created Dec. 14, 2002; gf_mult.h 1,155 byte created Dec. 14, 2002; hw.c 3,166 byte created Nov. 25, 2002; main.c 3,730 byte created Nov. 21, 2002; main_opt.c 4,537 byte created Nov. 25, 2002; main_patent.c 4,606 byte created Dec. 10, 2002; result 1,583 byte created Dec. 20, 2002 and ti_rs_{—}62×.pdf 711,265 byte created Dec. 17, 2002

The original implementation of code used as a reference was provided by Phil Karn. The files representing a simplified version of his original code are the following:

ccsds_tab.c

decode_rs.c

encode_rs.c

fixed.h

main.c

The optimized files for optimal software and hardware implementations are the following:

compile_patent.h

decode_rs_patent.c

encode_rs_patent.c

fixed_opt.h

main_patent.c

Conditional compilation is used within the different files to illustrate the implementation of different techniques. Optimization has been performed exploiting the sequential processing nature of the RS algorithm where one can avoid the copying of the CRC bytes by enlarging the array and using pointers to the current starting position. This optimization is significant toward actual implementation of the hardware assisted Reed Solomon.

The following files model the actual processing hardware implementation performed:

gf_mult.c

gf_mult.h

hw.c

### 9. Hardware Diagram Description

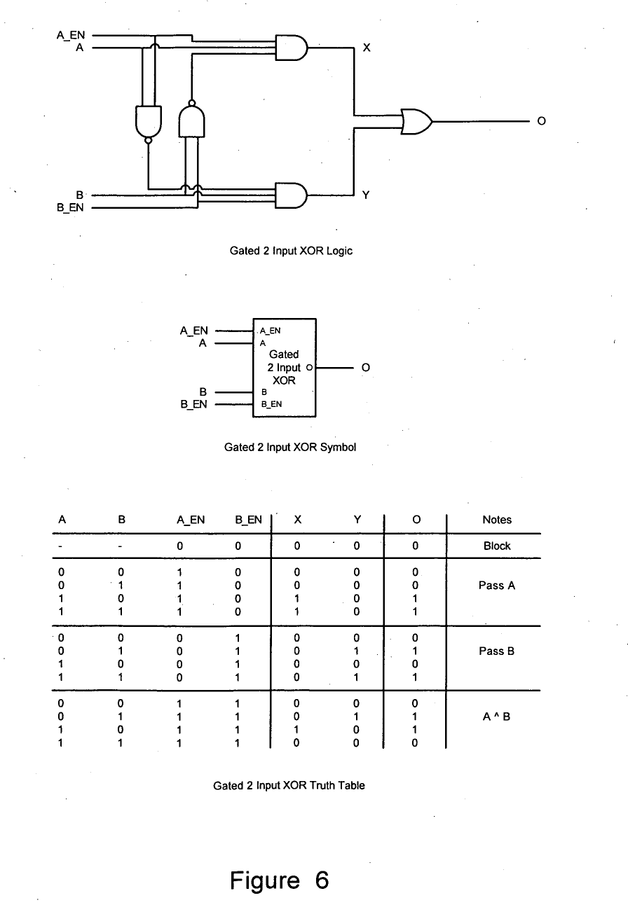

The diagrams show the hardware implementation of a primitive element (shown on FIG. 6) used within the GF hardware multiplier. Our basic unit is the Gated 2-Input XOR device. This device is used multiple times in each GF hardware multiplier.

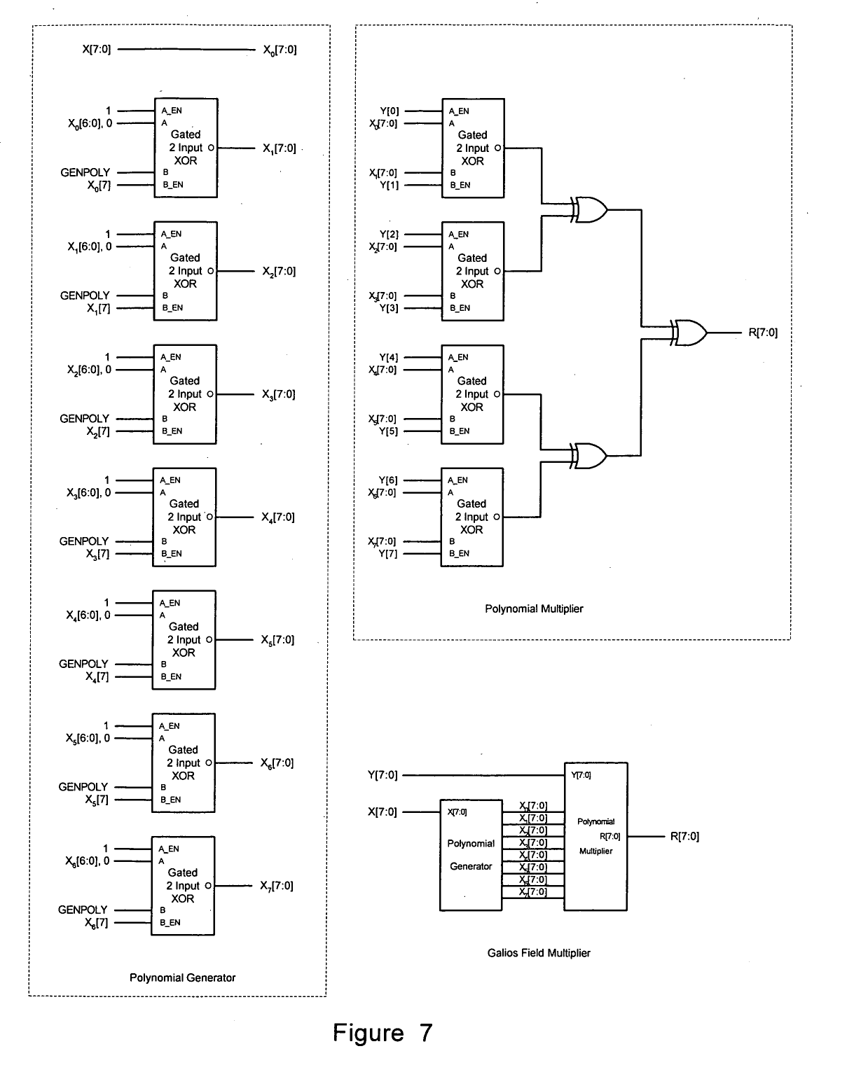

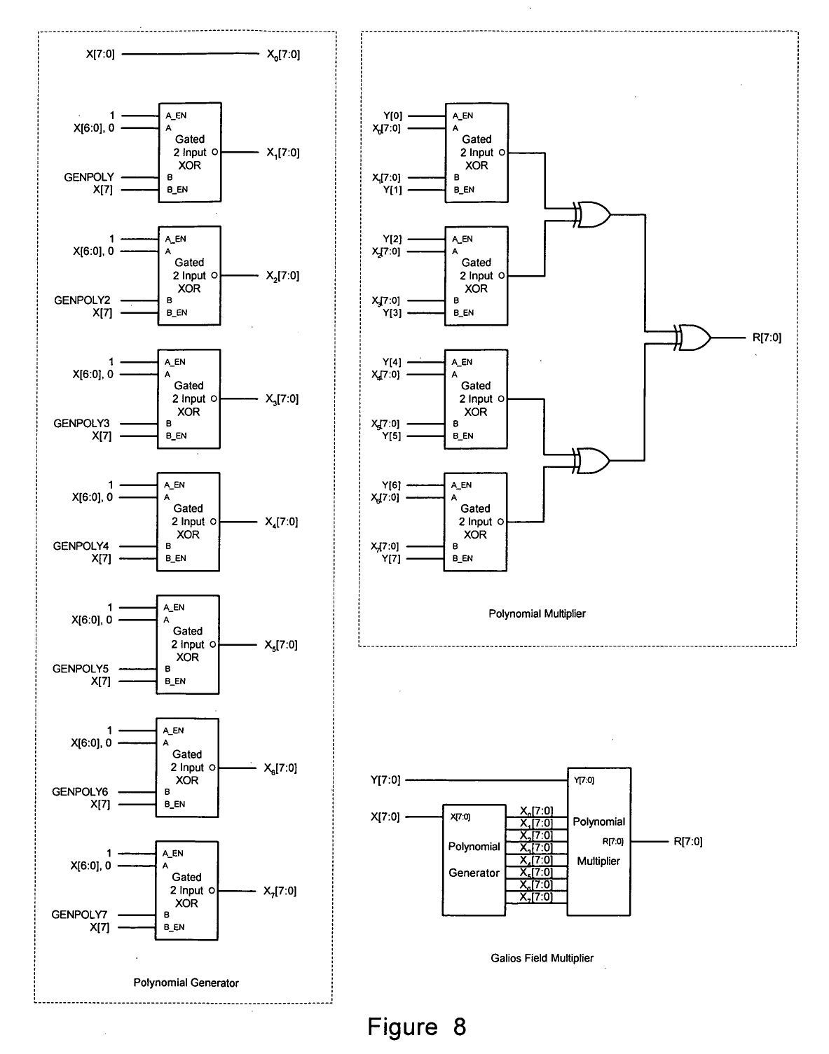

A single GF hardware multiplier is shown in FIG. 7 and is composed of two sub-units. The first is the Polynomial Generator and the second is the Polynomial Multiplier. The details of each are given on the left and right halves of the page and the sub-units are shown symbolically at the bottom right corner. An improved form of the Polynomial Generator is shown in FIG. 8 which is synthesized by combining constants representing powers of GENPOLY. The distributive and associative properties of Galios Field operations are applied to create the second through seventh powers of GENPOLY named GENPOLY2 to GENPOLY7 respectively. Unlike the previous implementation shown in FIG. 7, the X operand only needs to flow though a single Gated 2-Input XOR bank to generate all the Xi operands used by the Polynomial Multiplier block. This improved form results in reduced propagation delay of the circuits used in the GF hardware multiplier. This form is very suitable for high-speed pipelined applications when used in conjunction with a microprocessor core such as a MIPS processor.

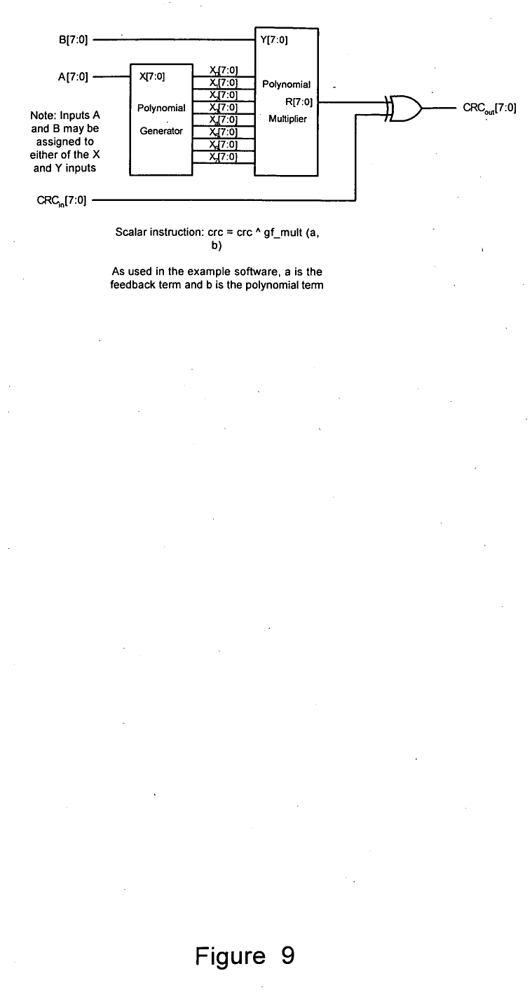

The scalar instruction implementation is shown in FIG. 9. The XOR operation for the CRC byte itself may be implemented as part of this instruction to consolidate the number of instructions needed. This feature is not however mandatory to practice the novel aspects of this invention.

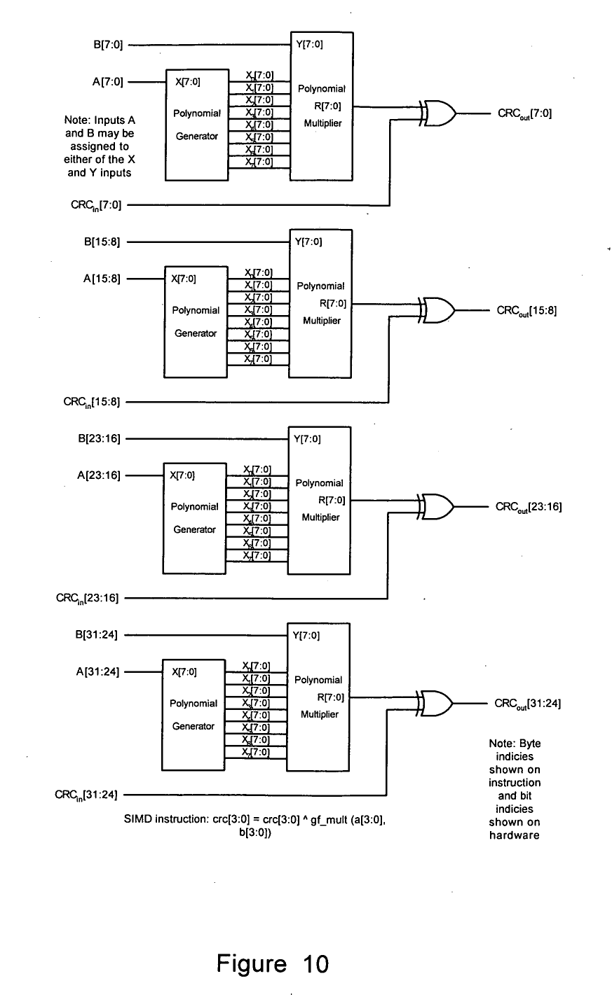

The 4×4 SIMD instruction implementation is shown in FIG. 10. The polynomial coefficients (either A or B inputs) may be delivered as part of the instruction or preferably through a ROM table associated with the instruction processing. The use of this ROM is not shown but is obvious to one skilled in the art.

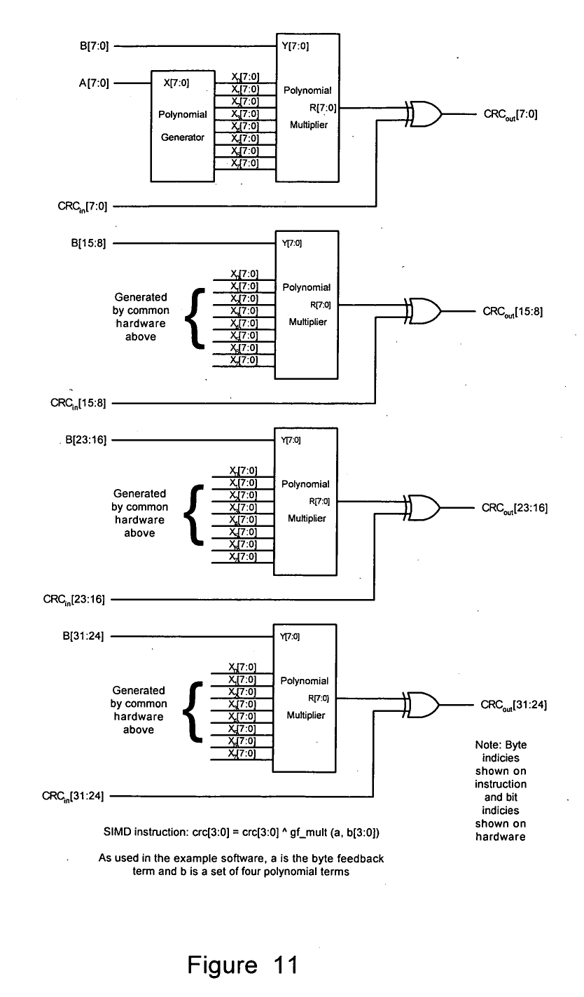

The implementation of the 1×4 SIMD instruction implementation is shown in FIG. 11. This one is similar to the 4×4 SIMD implementation except that a single byte feedback term is used for all four concurrent CRC updates. The 1×4 SIMD instruction would deliver the same data byte value on all 4 byte inputs such as the A[7:0], A[15:8], A[23:16] and A[31:24] byte-wide inputs.

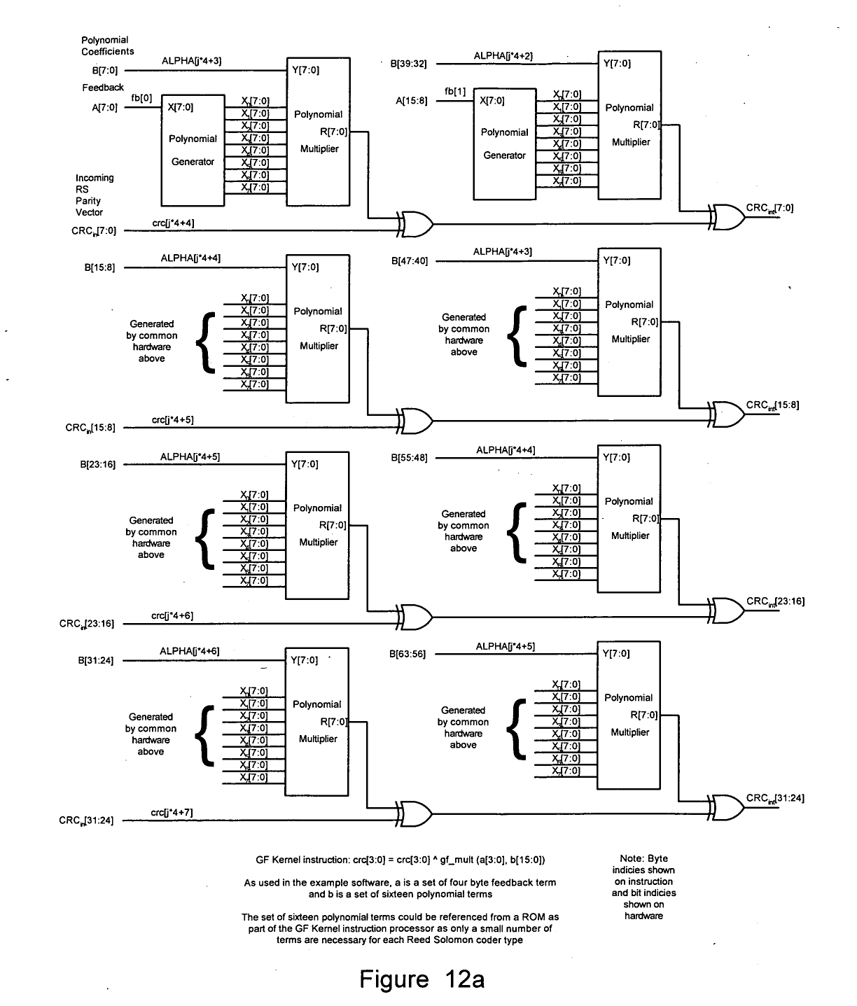

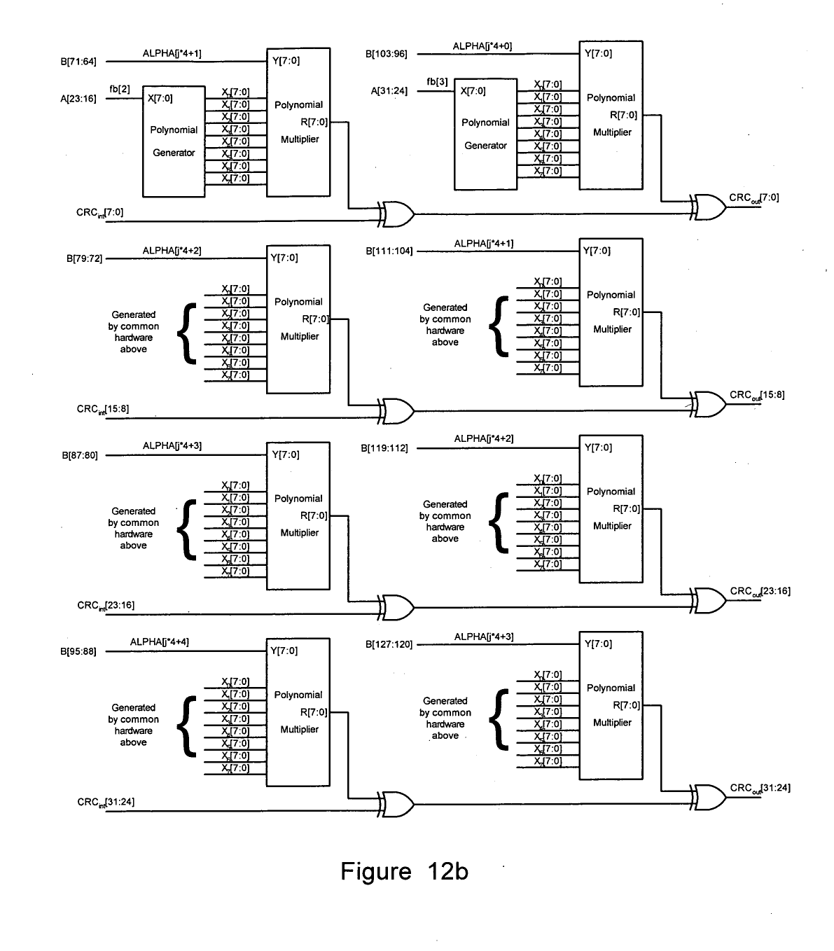

The RS Encode Kernel instruction is shown in FIG. 12. This unit performs 16 concurrent GF multiplications using different polynomial coefficients delivered by a ROM (selected by a field of the instruction). Notice that the software utilizing the GF Kernel is given in the file named “encode_rs_patent.c”. The instructions are shown in this file in groups of 16 individual scalar instructions each with a specific polynomial constant. The constant inputs may be exchanged with the feedback inputs for this instruction and the polynomial generation block would be repeated for each of the 16 multipliers. (The current structure exploits the fact that exactly four feedback terms are used in four multipliers each and hence only 4 polynomial generators are needed.) This apparent increase in hardware may be deceiving as the polynomial coefficients are all constants and are simply permuted by the polynomial generator to produce other constants. All of the polynomial generation hardware may simply be placed into a ROM. This eliminates several levels of logic and may allow implementation of the entire multiplier at faster clock rates. Possible pipelining is also not shown but is obvious to one skilled in the art. FIG. 12 also includes the following software variable names shown on the matching signals: ALPHA[j*4+0] to ALPHA[j*4+6], fb[0] to fb[3], and crc[j*4+4] to crc[j*4+7].

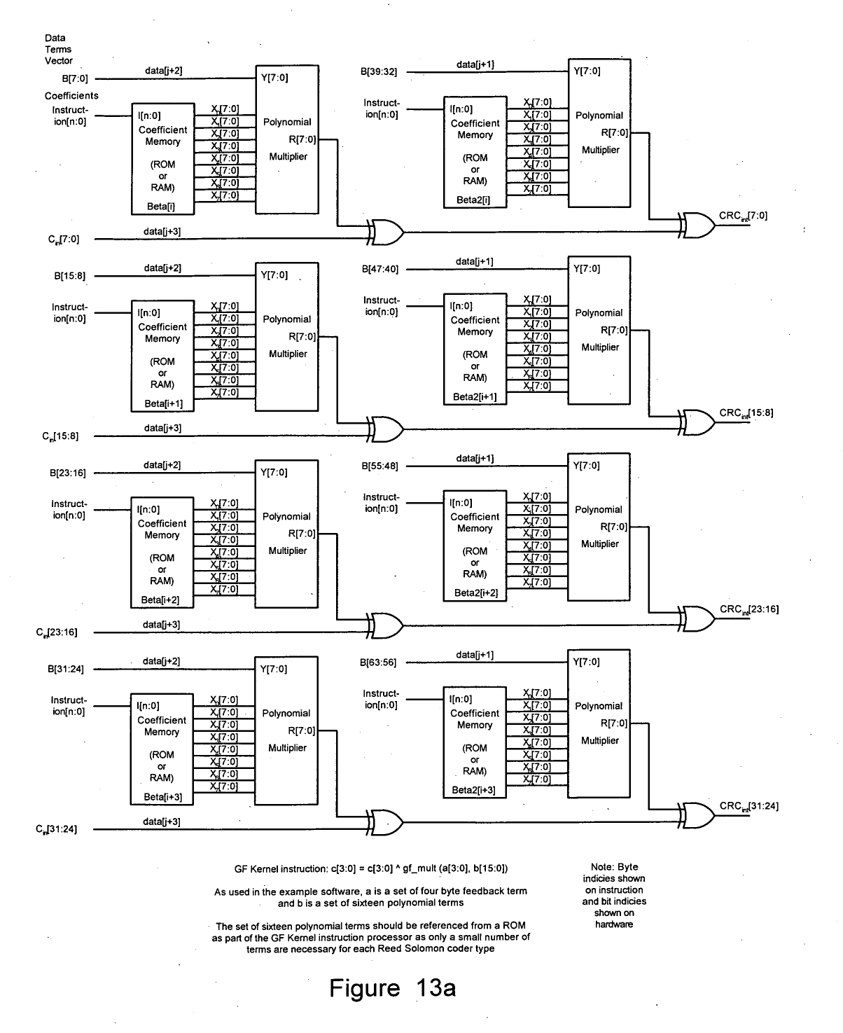

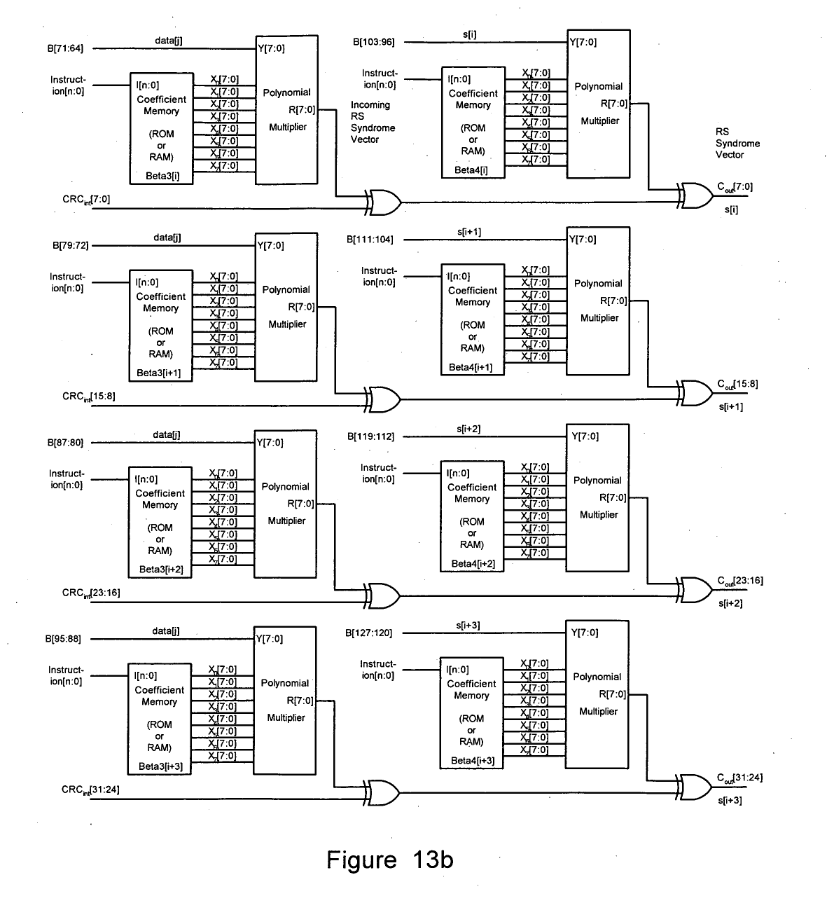

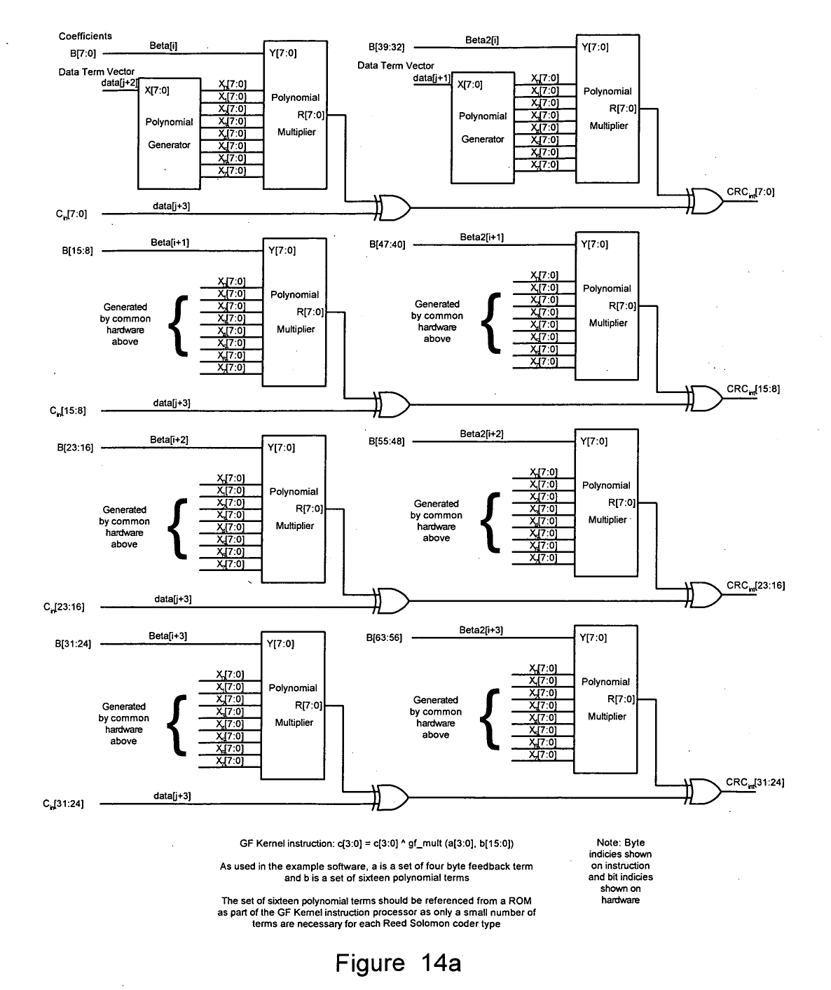

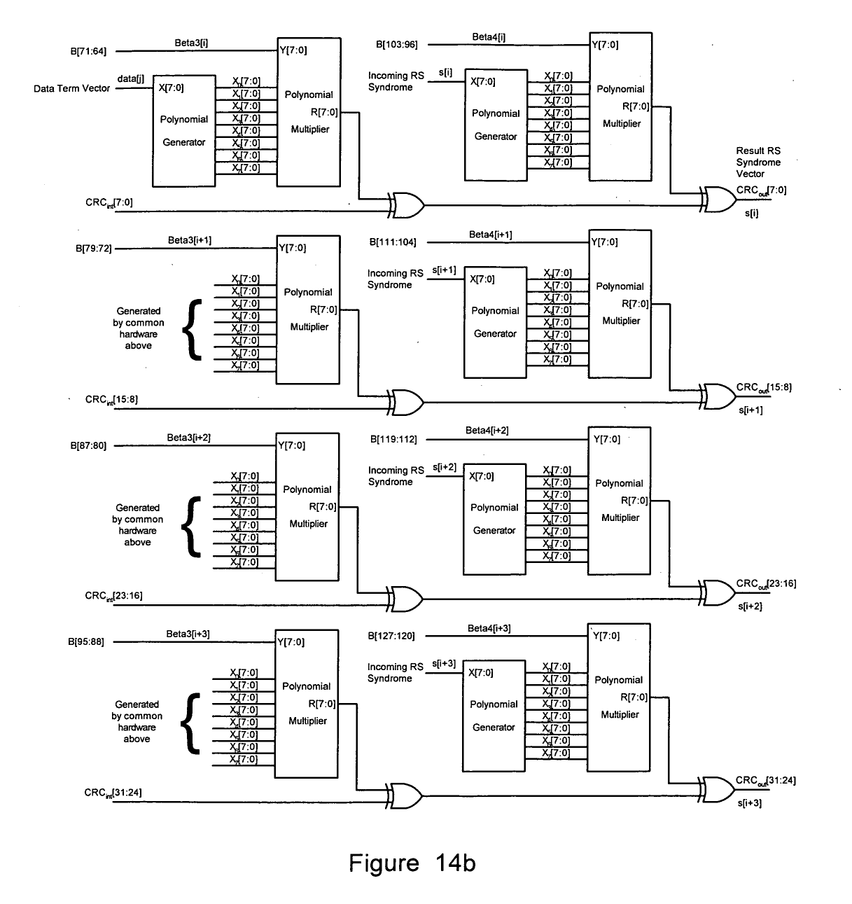

The RS Decode Kernel would use a similar structure as the encoder shown in FIG. 12. In one preferred embodiment, each multiplier needs its own independent polynomial coefficient coming from a ROM. The resulting structure, shown in FIG. 13, uses a ROM for each multiplier and replaces the polynomial generation hardware with the ROM. Each ROM block shown hence delivers 8 constants in parallel to each polynomial multiplier eliminating the polynomial generation. In another preferred embodiment, shown in FIG. 14, the polynomial generators are used instead of the wide ROM blocks and the BETA coefficients are delivered using the B signal inputs. This form may result in a more compact implementation and perform the equivalent processing. FIGS. 13 and 14 also includes the following software variable names shown on the matching signals: BETA[i] to BETA[i+3], BETA2[i] to BETA2[i+3], BETA3[i] to BETA3[i+3], BETA4[i] to BETA4[i+3], data[j] to data[j+3], and s[i] to s[i+3].

The hardware for implementing both RS Encode and Decode Kernel in common hardware would be based on FIG. 14. This structure is very similar to the encoder only structure shown in FIG. 12 with the addition of three polynomial generators in the rightmost column of polynomial multipliers. The ROM coefficients required for the Reed Solomon encode and decode kernels and for general scalar and SIMD Galios Field operations may be delivered through the B signal inputs. The instruction operands would be delivered by the processor to the A and CRC signal inputs and write the CRC signal outputs to as values to the processor register file. The scalar and SIMD Galios Field instructions would be exploited in the optimization of the error correction portion of the decoder as suggested by the representative C code in the file “decode_rs_patent.c”. Other RS decoder correction specific instructions may be developed in the spirit of this embodiment.

In a preferred embodiment, the parallelized method used in the generation of Reed Solomon parity bytes utilizes multiple digital logic operations or computer instructions implemented using digital logic illustrated in FIG. 12. At least one of the operations or instructions performs the following combinations of steps: a) provide an operand representing N feedback terms (fb[0] to fb[3]) where N is greater than one, b) provide an operand representing M incoming Reed Solomon parity bytes (crc[j*4+4] to crc[j*4+7]) where M is greater than one, c) computation of N by M Galios Field polynomial multiplications, d) computation of N by M Galios Field additions producing M modified Reed Solomon parity bytes (crcₒᵤₜ).

As shown in FIG. 12, the values of N and M were selected to be four as this matched the word width of the MIPS microprocessor. When N and M are both the value of four, sixteen Galios Field polynomial multiplications are computed concurrently or sequentially in a pipeline. Each Galios Field polynomial multiplication utilizes a coefficient (ALPHA[j*4+0] to ALPHA[j*4+6]) delivered from a memory device, which in a preferred embodiment, would be implemented by either a read only memory (ROM), random access memory (RAM) or a register file. The generation of Reed Solomon parity bytes requires several iterations each time using previous modified Reed Solomon parity bytes as incoming Reed Solomon parity bytes.

In a preferred embodiment, the parallelized method used in the generation of Reed Solomon syndrome bytes utilizes multiple digital logic operations or computer instructions implemented using digital logic illustrated in FIG. 14. At least one of the operations or instructions performs the following combinations of steps: a) provide an operand representing N data terms (data[j] to data[j+3]) where N is one or greater, b) provide an operand representing M incoming Reed Solomon syndrome bytes (s[i] to s[i+3]) where M is greater than one, c) computation of N by M Galios Field polynomial multiplications, d) computation of N by M Galios Field additions producing M modified Reed Solomon syndrome bytes (crc₀,t).

As shown in FIG. 14, the values of N and M were selected to be four as this matched the word width of the MIPS microprocessor. When N and M are both the value of four, sixteen Galios Field polynomial multiplications are computed concurrently or sequentially in a pipeline. Each Galios Field polynomial multiplication utilizes a coefficient (BETA[i] to BETA[i+3], BETA2[i] to BETA2[i+3], BETA3[i] to BETA3[i+3], BETA4[i] to BETA4[i+3]) delivered from a memory device, which in a preferred embodiment, would be implemented by either a read only memory (ROM), random access memory (RAM) or a register file. The generation of Reed Solomon syndrome bytes requires several iterations each time using previous modified Reed Solomon syndrome bytes as incoming Reed Solomon syndrome bytes.

What is claimed is:

1. A method used in the generation of Reed Solomon parity bytes utilizing multiple operations some of which are comprised of the following steps:
providing an operand representing N feedback terms where N is greater than one;
computation of N by M Galios Field polynomial multiplications where M is greater than one; and;
computation of (N−1) by M Galios Field additions producing M result bytes.

2. A method recited in claim 1, wherein said values of N and M are both the value of four resulting in computation of sixteen Galios Field polynomial multiplications.

3. A method recited in claim 1, wherein said computation of N by M Galios Field Polynomial multiplications occurs concurrently.

4. A method recited in claim 1, wherein said computation of N by M Galios Field Polynomial multiplications occurs sequentially in a pipeline.

5. A method recited in claim 1, wherein result bytes are used to modify Reed Solomon parity bytes in a separate operation.

6. A method recited in claim 1, wherein result bytes are used to modify Reed Solomon parity bytes in a same operation.

7. A method recited in claim 1, wherein each said Galios Field polynomial multiplication utilizes a coefficient delivered from a memory device.

8. A method recited in claim 7, where in said memory device include one or more elements of a group consisting of read only memory (ROM), random access memory (RAM) and a register file.

9. A method used in the generation of Reed Solomon parity bytes utilizing multiple operations some of which are comprised of the following steps:
providing an operand representing N feedback terms where N is greater than one;
providing an operand representing M incoming Reed Solomon parity bytes where M is greater than one,
computation of N by M Galios Field polynomial multiplications; and;
computation of N by M Galios Field additions producing M modified Reed Solomon parity bytes.

10. A method recited in claim 9, wherein said values of N and M are both the value of four resulting in computation of sixteen Galios Field polynomial multiplications.

11. A method recited in claim 9, wherein said generation of Reed Solomon parity bytes requires several iterations each time using previous modified Reed Solomon parity bytes as incoming Reed Solomon parity bytes.

12. A method used in the generation of Reed Solomon syndrome bytes utilizing multiple operations some of which are comprised of the following steps:
providing an operand representing N data terms where N is one or greater;
providing an operand representing M incoming Reed Solomon syndrome bytes where M is greater than one;
computation of N by M Galios Field polynomial multiplications; and;
computation of N by M Galios Field additions producing M modified Reed Solomon syndrome bytes.

13. A method recited in claim 12, wherein said values of N and M are both the value of four resulting in computation of sixteen Galios Field polynomial multiplications.

14. A method recited in claim 12, wherein said computation of N by M Galios Field Polynomial multiplications occurs concurrently.

15. A method recited in claim 12, wherein said computation of N by M Galios Field Polynomial multiplications occurs sequentially in a pipeline.

16. A method recited in claim 12, wherein said generation of Reed Solomon syndrome bytes requires several iterations each time using previous modified Reed Solomon syndrome bytes as incoming Reed Solomon syndrome bytes.

17. A method recited in claim 12, wherein each said Galios Field polynomial multiplication utilizes a coefficient delivered from a memory device.

18. A method recited in claim 17, wherein said memory device include one or more elements of a group consisting of read only memory (ROM), random access memory (RAM) and a register file.

19. A method recited in claim 17, wherein each said coefficient is derived using distributive and associative properties of Galios Field operations.

20. A method used to simplify coefficients used in a parallelized Reed Solomon decoder comprising:
expanding formulas for syndrome byte operations;
applying distributive and associative properties of Galios Field operations;
grouping multiple constants together using the same multiple type Galios Field operation; and;
forming a single aggregate constant in place of multiple constants and multiple operations.

21. An apparatus used for the generation of Reed Solomon parity bytes implemented in digital logic performing an operation which is comprised of the following:
means for providing an operand representing N feedback terms where N is greater than one;
means for computation of N by M Galios Field polynomial multiplications where M is greater than one; and;
means for computation of (N−1) by M Galios Field additions producing M result bytes.

22. An apparatus used in the generation of Reed Solomon parity bytes implemented in digital logic performing an operation which is comprised of the following:
means for providing an operand representing N feedback terms where N is greater than one;
means for providing an operand representing M incoming Reed Solomon parity bytes where M is greater than one;
means for computation of N by M Galios Field polynomial multiplications; and;
means for computation of N by M Galios Field additions producing M modified Reed Solomon parity bytes.

23. An apparatus used in the generation of Reed Solomon syndrome bytes implemented in digital logic performing an operation which is comprised of the following:
means for providing an operand representing N data terms where N is one or greater;
means for providing an operand representing M incoming Reed Solomon syndrome bytes where M is greater than one;
means for computation of N by M Galios Field polynomial multiplications; and;
means for computation of N by M Galios Field additions producing M modified Reed Solomon syndrome bytes.
